(19) United States
(12) Patent Application Publication
(10) Pub. No.: US 2023/0301003 A1
(43) Pub. Date: Sep. 21, 2023

(54) COVER ARTICLES WITH DURABLE OPTICAL STRUCTURES AND FUNCTIONAL COATINGS, AND METHODS OF MAKING THE SAME

(71) Applicants: CORNING INCORPORATED, Corning, NY (US); CORNING PRECISION MATERIALS Co., LTD., Asan-si (KR)

(72) Inventors: Carlo Anthony Kosik Williams, Painted Post, NY (US); Jeonghong Oh, Cheonan-si (KR); Jung-keun Oh, Gwangmyeong-si (KR); Sang-Yoon Oh, Cheonan City (KR)

(21) Appl. No.: 18/123,398

(22) Filed: Mar. 20, 2023

Related U.S. Application Data
(60) Provisional application No. 63/321,909, filed on Mar. 21, 2022.

(51) Int. Cl. H05K 5/03; H05K 5/02; H05K 5/00; G02B 1/14; G02B 1/18; G02B 1/12; G02B 13/00; B29D 11/00; B32B 17/10; G02B 1/11

(52) U.S. Cl. CPC H05K 5/03; H05K 5/0247; H05K 5/0018; G02B 1/14; G02B 1/18; G02B 1/12; G02B 13/001; B29D 11/00865; B32B 17/10128; G02B 1/11

(57) ABSTRACT

A cover article is described herein that includes: a substrate having a primary surface; an optical structure disposed on the primary surface, wherein the optical structure comprises an optical coating and a scratch resistant layer, and wherein the optical coating has an outer surface; and an easy-to-clean (ETC) coating disposed on the outer surface of the optical coating, wherein the ETC coating comprises a fluorine-containing material. The outer surface of the optical coating has a surface roughness (Ra) less than 1.5 nm. The optical structure has a physical thickness of greater than or equal to 500 nm and a maximum hardness of 10 GPa or greater, as measured on the outer surface of the optical coating by a Berkovich Indenter Test along an indentation depth of 50 nm or greater. The scratch resistant layer has a physical thickness from 200 nm to 5000 nm.

### CLAIM OF PRIORITY

This application claims the benefit of priority under 35 U.S.C. § 119 of U.S. Provisional Application No. 63/321,909 filed Mar. 21, 2022, the content of which is incorporated herein by reference in its entirety.

### FIELD

This disclosure relates to articles for protection of display and other electronic devices, particularly cover articles with a durable functional coating (e.g., an easy-to-clean coating) and optical structures (e.g., antireflective coatings) configured to exhibit desired optical properties and to enhance the durability of the functional coating, along with methods of making these articles.

### BACKGROUND

Cover articles with glass substrates are often used to protect critical devices and components within electronic products and systems, such as mobile devices, smart phones, computer tablets, hand-held devices, vehicular displays and other electronic devices with displays, cameras, light sources and/or sensors. These cover articles can also be employed in architectural articles, transportation articles (e.g., articles used in automotive applications, trains, aircraft, sea craft, etc.), appliance articles, or any article that requires some transparency, scratch resistance, abrasion resistance, or a combination thereof.

These applications that employ cover glass articles often demand a combination of mechanical and environmental durability, fingerprint resistance, breakage resistance, damage resistance, scratch resistance and strong optical performance characteristics. In some applications, the cover articles are required to cover and protect display devices, cameras, sensors and/or light sources. Often, cover articles are configured with multilayer optical coatings configured such that the cover article exhibits certain combinations of optical properties. For example, the cover articles may be required to exhibit high light transmittance, low reflectance and/or low transmitted color in the visible spectrum and employ optical coatings configured to achieve acceptable levels of these properties.

Conventional cover articles often employ hydrophobic and/or oleophobic functional coatings, often referred to as “anti-fingerprint”, “anti-smudge”, and “easy-to-clean” coatings, over their optical coatings and structures. These easy-to-clean coatings can reduce surface damage due to their lubricious nature. They can also reduce or eliminate fingerprints and facilitate easy cleaning of foreign objects and materials. Nevertheless, the durability of easy-to-clean coatings has been found to be inferior when used in combination with an underlying optical coating. That is, the durability of easy-to-clean coatings disposed over an optical coating and substrate has been found to be significantly reduced or degraded relative to easy-to-clean coatings disposed directly on the substrate. As such, conventional cover articles are often limited in their ability to exhibit a combination of optical properties and fingerprint resistance.

Accordingly, there is a need for improved cover articles for protection of optical articles and devices, particularly cover articles with a durable functional coating (e.g., an easy-to-clean coating) and optical structures (e.g., antireflective coatings) configured to exhibit desired optical properties and to enhance the durability of the functional coating. There is also a need for methods of making these cover articles. These needs, and other needs, are addressed by the present disclosure.

### SUMMARY

According to an aspect of the disclosure, a cover article is provided that includes: a substrate having a primary surface; an optical structure disposed on the primary surface, wherein the optical structure comprises an optical coating and a scratch resistant layer, and wherein the optical coating has an outer surface opposing the primary surface of the substrate; and an easy-to-clean (ETC) coating disposed on the outer surface of the optical coating, wherein the ETC coating comprises a fluorine-containing material. The outer surface of the optical coating has a surface roughness (Ra) less than 1.5 nm. The optical structure has a physical thickness of greater than or equal to 500 nm and a maximum hardness of 10 GPa or greater, as measured on the outer surface of the optical coating by a Berkovich Indenter Test along an indentation depth of 50 nm or greater. The scratch resistant layer has a physical thickness from 200 nm to 5000 nm.

According to an aspect of the disclosure, a cover article is provided that includes: a substrate having a primary surface; an optical structure disposed on the primary surface, wherein the optical structure comprises an optical coating and a scratch resistant layer, and wherein the optical coating has an outer surface opposing the primary surface of the substrate; and an easy-to-clean (ETC) coating disposed on the outer surface of the optical coating, wherein the ETC coating comprises a fluorine-containing material. The outer surface of the optical coating has a surface roughness (Ra) less than 1.5 nm. The optical structure has a physical thickness of greater than or equal to 500 nm and a maximum hardness of 10 GPa or greater, as measured on the outer surface of the optical coating by a Berkovich Indenter Test along an indentation depth of 50 nm or greater. The scratch resistant layer has a physical thickness from 200 nm to 5000 nm. Further, the optical coating comprises a plurality of high refractive index (RI) layers and low RI layers, wherein each of the low RI layers comprises a refractive index of less than or equal to about 1.8, and each of the high RI layers comprises a refractive index of greater than 1.8. Each high RI layer comprises one of AlOₓN_{y}, Nb₂O, TiO₂, Si₃N₄, SiNₓ and SiOₓN_{y}, and each low RI layer comprises one of SiO₂, SiOₓ, and MgF₂. In addition, the scratch resistant layer comprises any one of AlOₓN_{y}, Si₃N₄, SiNₓ and SiOₓN_{y}.

According to an aspect of the disclosure, a cover article is provided that includes: a substrate having a primary surface; an optical structure disposed on the primary surface, wherein the optical structure comprises an optical coating and a scratch resistant layer, and wherein the optical coating has an outer surface opposing the primary surface of the substrate; and an easy-to-clean (ETC) coating disposed on the outer surface of the optical coating, wherein the ETC coating comprises a fluorine-containing material. The outer surface of the optical coating has a surface roughness (Ra) less than 1.5 nm. The optical structure has a physical thickness of greater than or equal to 750 nm and a maximum hardness of 10 GPa or greater, as measured on the outer surface of the optical coating by a Berkovich Indenter Test along an indentation depth of 50 nm or greater. The scratch resistant layer has a physical thickness from 250 nm to 2500 nm. In addition, the scratch resistant layer is within the optical coating. Further, the optical coating comprises a plurality of high refractive index (RI) layers and low RI layers, wherein each of the low RI layers comprises a refractive index of less than or equal to about 1.8, and each of the high RI layers comprises a refractive index of greater than 1.8. Each high RI layer comprises one of Si₃N₄, SiNₓ and SiOₓN_{y}, and each low RI layer comprises one of SiO₂ and SiOₓ. In addition, the scratch resistant layer comprises any one of Si₃N₄, SiNₓ and SiOₓN_{y}.

According to another aspect of the disclosure, a method of making a cover article is provided that includes: providing a substrate having a primary surface; depositing an optical structure on the primary surface, wherein the optical structure comprises an optical coating and a scratch resistant layer, and wherein the optical coating has an outer surface opposing the primary surface of the substrate; modifying the outer surface of the optical coating, wherein the outer surface of the optical coating has a surface roughness (Ra) less than 1.5 nm after the step of modifying the outer surface; depositing an easy-to-clean (ETC) coating on the outer surface of the optical coating after the step of modifying the outer surface, wherein the ETC coating comprises a fluorine-containing material; and curing the ETC coating. The optical structure has a physical thickness of greater than or equal to 500 nm and a maximum hardness of 10 GPa or greater, as measured on the outer surface of the optical coating by a Berkovich Indenter Test along an indentation depth of 50 nm or greater. Further, the scratch resistant layer has a physical thickness from 200 nm to 5000 nm. In addition, the ETC coating exhibits a water contact angle of greater than 95° after 1000 cycles in a Steel Wool Abrasion Test after the step of curing the ETC coating.

Additional features and advantages will be set forth in the detailed description which follows, and in part will be readily apparent to those skilled in the art from that description or recognized by practicing the embodiments as described herein, including the detailed description which follows, the claims, as well as the appended drawings.

### BRIEF DESCRIPTION OF THE DRAWINGS

It is to be understood that both the foregoing general description and the following detailed description are merely exemplary, and are intended to provide an overview or framework to understanding the nature and character of the claims. The accompanying drawings are included to provide a further understanding, and are incorporated in and constitute a part of this specification. The drawings illustrate one or more embodiments, and together with the description serve to explain principles and operation of the various embodiments, wherein:

FIG. 1A is a cross-sectional side view of a cover article (e.g., for a display device), according to an embodiment of the disclosure;

FIG. 1B is a cross-sectional side view of a cover article, according to an embodiment of the disclosure;

FIGS. 2A-2C are cross-sectional schematics of an easy-to-clean coating on a substrate and an easy-to-clean coating on each of two antireflective films having different surface roughness levels over a substrate;

FIG. 3A is a cross-sectional schematic of an apparatus for conducting a Steel Wool Abrasion Test on a cover article, according to an embodiment of the disclosure;

FIG. 3B is a cross-sectional schematic of a cover article, after being subjected to a Steel Wool Test, according to an embodiment of the disclosure;

FIG. 4 is a flow chart schematic of a method of making a cover article, according to an embodiment of the disclosure;

FIG. 4A is a schematic of a step of modifying the outer surface of a cover article according to the method depicted in FIG. 4, according to an embodiment of the disclosure;

FIG. 5A is a plan view of an exemplary electronic device incorporating any of the cover articles disclosed herein;

FIG. 5B is a perspective view of the exemplary electronic device of FIG. 5A;

FIG. 6 is a plot of average water contact angle measurements on samples from various comparative articles (relative to cover articles of the disclosure), as subjected to a Steel Wool Abrasion Test for 0, 1000, 2000 and 3000 cycles;

FIG. 7A is a plot of surface roughness vs. treatment time of the outer surface of an optical coating of cover articles, as subjected to plasma treatments at various power levels, according to embodiments of the disclosure;

FIG. 7B is a plot of first-surface reflectance vs. visible wavelengths for cover articles prepared according to treatments depicted in FIG. 7A, according to embodiments of the disclosure; and

FIGS. 7C and 7D are plots of average water contact angle measurements on cover article samples prepared according to the treatments depicted in FIG. 7A, as subjected to a Steel Wool Abrasion Test for 2000 and 3000 cycles, respectively, according to embodiments of the disclosure.

### DETAILED DESCRIPTION

In the following detailed description, for purposes of explanation and not limitation, example embodiments disclosing specific details are set forth to provide a thorough understanding of various principles of the present disclosure. However, it will be apparent to one having ordinary skill in the art, having had the benefit of the present disclosure, that the present disclosure may be practiced in other embodiments that depart from the specific details disclosed herein. Moreover, descriptions of well-known devices, methods and materials may be omitted so as not to obscure the description of various principles of the present disclosure. Finally, wherever applicable, like reference numerals refer to like elements.

Ranges can be expressed herein as from “about” one particular value, and/or to “about” another particular value. When such a range is expressed, another embodiment includes from the one particular value and/or to the other particular value. Similarly, when values are expressed as approximations, by use of the antecedent “about,” it will be understood that the particular value forms another embodiment. It will be further understood that the endpoints of each of the ranges are significant both in relation to the other endpoint, and independently of the other endpoint.

Directional terms as used herein—for example “up,” “down,” “right,” “left,” “front,” “back,” “top,” “bottom”—are made only with reference to the figures as drawn and are not intended to imply absolute orientation.

Unless otherwise expressly stated, it is in no way intended that any method set forth herein be construed as requiring that its steps be performed in a specific order. Accordingly, where a method claim does not actually recite an order to be followed by its steps, or it is not otherwise specifically stated in the claims or descriptions that the steps are to be limited to a specific order, it is in no way intended that an order be inferred, in any respect. This holds for any possible non-express basis for interpretation, including: matters of logic with respect to arrangement of steps or operational flow; plain meaning derived from grammatical organization or punctuation; the number or type of embodiments described in the specification.

As used herein, the singular forms “a,” “an” and “the” include plural referents unless the context clearly dictates otherwise. Thus, for example, reference to a “component” includes aspects having two or more such components, unless the context clearly indicates otherwise.

As used herein, the term “dispose” includes coating, depositing, and/or forming a material onto a surface using any known or to be developed method in the art. The disposed material may constitute a layer, as defined herein. As used herein, the phrase “disposed on” includes forming a material onto a surface such that the material is in direct contact with the surface and embodiments where the material is formed on a surface with one or more intervening material(s) disposed between material and the surface. The intervening material(s) may constitute a layer, as defined herein.

As used herein, the terms “low RI layer” and “high RI layer” refer to the relative values of the refractive index (“RI”) of layers of an optical structure of a cover article according to the disclosure (i.e., low RI layer<high RI layer). Hence, low RI layers have refractive index values that are less than the refractive index values of high RI layers. Further, as used herein, “low RI layer” and “low index layer” are interchangeable with the same meaning. Likewise, “high RI layer” and “high index layer” are interchangeable with the same meaning.

As used herein, the term “strengthened substrate” refers to a substrate employed in a cover article of the disclosure that has been chemically strengthened, for example through ion-exchange of larger ions for smaller ions in the surface of the substrate. However, other strengthening methods known in the art, such as thermal tempering, or utilizing a mismatch of the coefficient of thermal expansion between portions of the substrate to create compressive stress and central tension regions, may be utilized to form strengthened substrates.

As used herein, the “Berkovich Indenter Hardness Test”, “Berkovich Hardness Test” and “Berkovich Indenter Test” are used interchangeably to refer to a test for measuring the hardness of a material on a surface thereof by indenting the surface with a diamond Berkovich indenter. The Berkovich Indenter Hardness Test includes indenting the outermost surface (e.g., an exposed surface) of a single optical structure or the outer optical structure of a cover article of the disclosure with the diamond Berkovich indenter to form an indent to an indentation depth in the range from about 50 nm to about 1000 nm (or the entire thickness of the outer or inner optical structure, whichever is less) and measuring the maximum hardness from this indentation along the entire indentation depth range or a segment of this indentation depth (e.g., in the range from about 100 nm to about 600 nm), generally using the methods set forth in Oliver, W. C.; Pharr, G. M. An improved technique for determining hardness and elastic modulus using load and displacement sensing indentation experiments. J. Mater. Res., Vol. 7, No. 6, 1992, 1564-1583; and Oliver, W. C.; Pharr, G. M. Measurement of Hardness and Elastic Modulus by Instrument Indentation: Advances in Understanding and Refinements to Methodology. J. Mater. Res., Vol. 19, No. 1, 2004, 3-20. As used herein, each of “hardness” and “maximum hardness” interchangeably refers to a maximum hardness as measured along a range of indentation depths, and not an average hardness.

As used herein, the term “transmittance” is defined as the percentage of incident optical power within a given wavelength range transmitted through a material (e.g., the article, the substrate or the optical film or portions thereof). The term “reflectance” is similarly defined as the percentage of incident optical power within a given wavelength range that is reflected from a material (e.g., the cover article, its substrate, optical structure, or optical coating, or portions thereof). Transmittance and reflectance are measured using a specific linewidth. As used herein, an “average transmittance” refers to the average amount of incident optical power transmitted through a material over a defined wavelength regime. As used herein, an “average reflectance” refers to the average amount of incident optical power reflected by the material.

As used herein, “photopic reflectance” mimics the response of the human eye by weighting the reflectance or transmittance, respectively, versus wavelength spectrum according to the human eye's sensitivity. Photopic reflectance may also be defined as the luminance, or tristimulus Y value of reflected light, according to known conventions such as CIE color space conventions. The “average photopic reflectance”, as used herein, for a wavelength range from 380 nm to 720 nm is defined in the below equation as the spectral reflectance, R(λ) multiplied by the illuminant spectrum, I(X) and the CIE's color matching function y̅(λ), related to the eye's spectral response:

$$〈 {R}_{p} 〉 = {{\int }^{720 nm}}_{380 nm} R ( λ ) \times I ( λ ) \times \overline{y} ( λ ) d λ$$

In addition, “average reflectance” can be determined over the visible spectrum, or over other wavelength ranges, according to measurement principles understood by those skilled in the field of the disclosure, e.g., in the infrared spectrum from 840 nm to 950 nm, etc. Unless otherwise noted, all reflectance values reported or otherwise referenced in this disclosure are associated with testing through both primary surfaces of the substrate and optical structure of the cover articles of the disclosure, e.g., a “two-surface” average photopic reflectance. In cases where “one-surface” or “first-surface” reflectance is specified, the reflectance from the rear surface of the cover article is eliminated through optical bonding to a light absorber, allowing the reflectance of only the first surface to be measured.

The usability of a cover article in an electronic device (e.g., as a protective cover) can be related to the total amount of reflectance in the article. Photopic reflectance is particularly important for display devices that employ visible light. Lower reflectance in a cover article over a lens and/or a display associated with the device can reduce multiple-bounce reflections in the device that can generate ‘ghost images’. Thus, reflectance has an important relationship to image quality associated with the device, particularly its display and any of its other optical components (e.g., a lens of a camera). Low-reflectance displays also enable better display readability, reduced eye strain, and faster user response time (e.g., in an automotive display, where display readability can also correlate to driver safety). Low-reflectance displays can also allow for reduced display energy consumption and increased device battery life, since the display brightness can be reduced for low-reflectance displays compared to standard displays, while still maintaining the targeted level of display readability in bright ambient environments.

As used herein, “photopic transmittance” is defined in the below equation as the spectral transmittance, T(λ) multiplied by the illuminant spectrum, I(λ) and the CIE's color matching function y̅(λ), related to the eye's spectral response:

$$〈 {T}_{p} 〉 = {{\int }^{720 nm}}_{380 nm} T ( λ ) \times I ( λ ) \times \overline{y} ( λ ) d λ$$

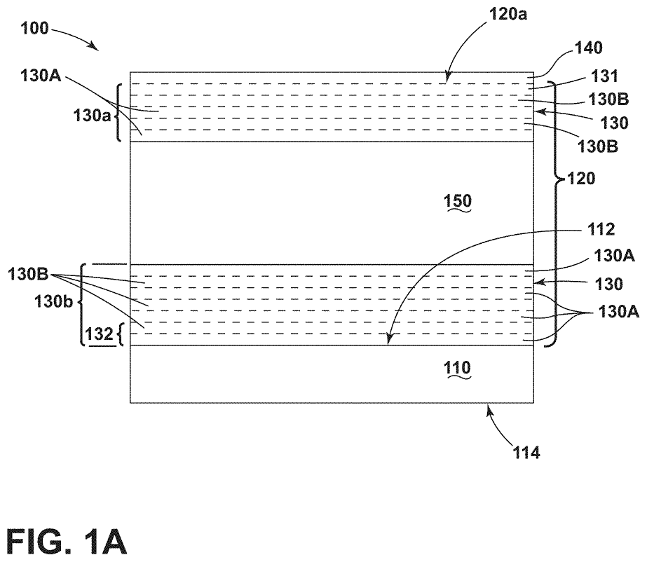

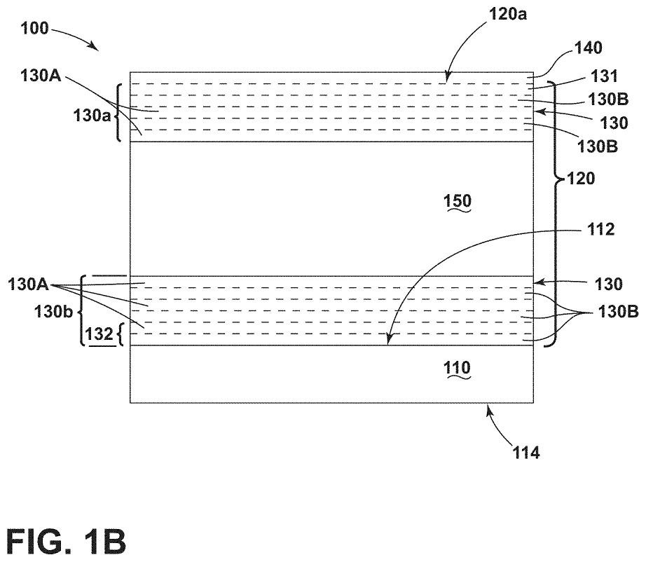

In addition, “average transmittance” or “average photopic transmittance” can be determined over the visible spectrum or other wavelength ranges, according to measurement principles understood by those skilled in the field of the disclosure, e.g., in the infrared spectrum from 840 nm to 950 nm, etc. Unless otherwise noted, all transmittance values reported or otherwise referenced in this disclosure and claims are associated with testing through both primary surfaces of the substrate and the optical structure (e.g., the substrate 110, primary surfaces 112, 114, and optical structure 120 as shown in FIGS. 1A and 1, described below) of the cover articles, e.g., a “two-surface” average photopic transmittance.

Generally, the disclosure is directed to cover articles that employ structures over glass and glass-ceramic substrates, including strengthened substrates. Further, these cover articles include a functional, high durability coating (e.g., an easy-to-clean coating) on a high-hardness optical structure configured to ensure that the cover article exhibits certain optical properties, such as low reflectance. Notably, the structural characteristics of the optical structure can be configured to improve and influence the durability of the functional coating. Further, the disclosure includes methods of making these cover articles, including process steps (e.g., a plasma surface treatment process, mechanical polishing, chemical etching, etc.) for configuring the optical structure to improve and influence the durability of the overlying functional coating.

The cover articles of the disclosure can be employed for protection and/or covers of displays, camera lenses, sensors and/or light source components within or otherwise part of electronic devices, along with protection of other components (e.g., buttons, speakers, microphones, etc.). These cover articles with a protective function employ an optical structure disposed on a substrate such that the article exhibits a combination of high hardness, high damage resistance and desirable optical properties, including low reflectance. The optical structure can include a scratch resistant layer, at any of various locations within the structure. Further, the optical structures of these cover articles can include a plurality of alternating high and low refractive index layers, with each high index layer and a scratch resistant layer comprising a nitride or an oxynitride and each low index layer comprising an oxide.

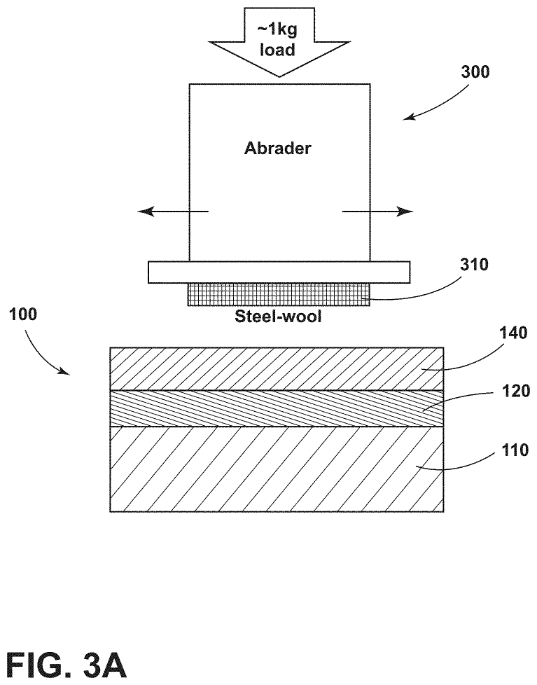

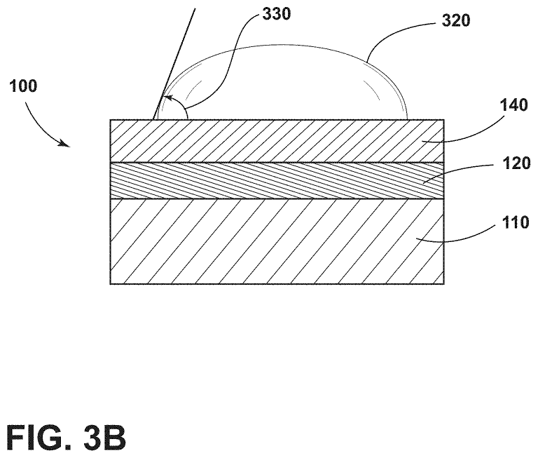

In general, these cover articles include a functional coating (e.g., an easy-to-clean coating comprising a fluorine-containing material) with high durability, e.g., a water contact angle of greater than 95° after 1000 cycles in a Steel Wool Abrasion Test (see FIGS. 3A and 3B, and corresponding description later in the disclosure). Notably, the durability of the functional coating of these cover articles can be driven or otherwise influenced by the surface roughness of their optical structures. For example, aspects of the cover articles of the disclosure are configured such that the outer surface of the optical coating of the optical structure possesses a surface roughness (Ra) of less than 1.5 nm, less than 1.2 nm, or even less than 1.0 nm. In some aspects, the functional coating of the cover article is particularly durable with a water contact angle of greater than 100°, or even 105°, after 2000 cycles, or even 3000 cycles, in a Steel Wool Abrasion Test.

With general regard to mechanical properties, the cover articles of the disclosure, and/or the optical structures of these cover articles, can exhibit a maximum hardness of 10 GPa or greater, or 12 GPa or greater (or even greater than 14 GPa in some instances), as measured by a Berkovich Hardness Test along an indentation depth of 50 nm or greater. In terms of optical properties, the cover articles of the disclosure can exhibit a first-surface average photopic reflectance of less than 10%, less than 5%, or even less than 1%, at any incident angle from normal or near-normal (e.g., 5°) to about 20° at wavelengths in the visible spectrum, e.g., from 450 nm to 650 nm.

Referring to FIGS. 1A and 1B, a cover article 100 according to one or more embodiments includes a substrate 110, and an optical structure 120 defining an outer surface 120a and an inner surface 120b disposed on the substrate 110. The substrate 110 includes opposing primary surfaces 112, 114. The optical structure 120 is shown in FIGS. 1A and 1B, with its inner surface 120b disposed on a first opposing primary surface 112 and no optical structures are shown as being disposed on the second opposing primary surface 114. In some embodiments, however, an optical structure 120 can also (or alternatively) be disposed on the second opposing primary surface 114.

The optical structure 120 includes at least one layer of material. As used herein, the term “layer” may include a single layer or may include one or more sub-layers. Such sub-layers may be in direct contact with one another. The sub-layers may be formed from the same material or two or more different materials. In one or more alternative embodiments, such sub-layers may have intervening layers of different materials disposed therebetween. In one or more embodiments, a layer may include one or more contiguous and uninterrupted layers and/or one or more discontinuous and interrupted layers (i.e., a layer having different materials formed adjacent to one another). A layer or sub-layer may be formed by any known method in the art, including discrete deposition or continuous deposition processes. In one or more embodiments, the layer may be formed using only continuous deposition processes, or, alternatively, only discrete deposition processes.

In one or more embodiments, a single layer or multiple layers of the optical structure 120 may be deposited onto the substrate 110 by a vacuum deposition technique such as, for example, chemical vapor deposition (e.g., plasma enhanced chemical vapor deposition (PECVD), low-pressure chemical vapor deposition, atmospheric pressure chemical vapor deposition, and plasma-enhanced atmospheric pressure chemical vapor deposition), physical vapor deposition (e.g., reactive or nonreactive sputtering or laser ablation), thermal or e-beam evaporation and/or atomic layer deposition. Liquid-based methods may also be used such as spraying, dipping, spin coating, or slot coating (e.g., using sol-gel materials). Generally, vapor deposition techniques may include a variety of vacuum deposition methods which can be used to produce thin films. For example, physical vapor deposition uses a physical process (such as heating or sputtering) to produce a vapor of material, which is then deposited on the object which is coated. Preferred methods of fabricating the optical structure 120 can include reactive sputtering, metal-mode reactive sputtering and PECVD processes.

The optical structure 120 may have a thickness of from about 500 nm to about 10 microns. In embodiments of the cover article 100 depicted in FIGS. 1A and 1B, the optical structure 120 may have a thickness greater than or equal to about 500 nm, 600 nm, 700 nm, 750 nm, 800 nm, 900 nm, 1 micron (i.e., 1000 nm), 1.25 microns, 1.5 microns, 1.75 microns, 2 microns, 3 microns, 4 microns, 5 microns, 6 microns, 7 microns, or even 8 microns, and less than or equal to about 10 microns. For example, the optical structure 120 can have a thickness of about 500 nm, 750 nm, 1000 nm, 1250 nm, 1500 nm, 1750 nm, 2000 nm, 2500 nm, 3000 nm, 4000 nm, 5000 nm, 7500 nm, 10000 nm, and all thickness values between the foregoing ranges and sub-ranges.

In embodiments, as depicted for example in FIGS. 1A and 1B, the optical structure 120 comprises an optical coating 130 that is divided into an outer structure 130a and an inner structure 130b, with a scratch resistant layer 150 (as detailed further below) disposed between the structures 130a and 130b. In these embodiments, the outer and inner optical structures 130a and 130b of the optical coating 130 may have the same thicknesses or different thicknesses, and each comprises one or more layers.

Referring again to the cover article 100 depicted in FIGS. 1A and 1B, the optical structure 120 includes one or more scratch resistant layers 150. For example, the cover article 100 depicted in FIGS. 1A and 1B includes an optical structure 120 with a scratch resistant layer 150 disposed over a primary surface 112 of the substrate 110. According to one embodiment, the scratch resistant layer 150 may comprise one or more materials chosen from SiᵤAlᵥOₓN_{y}, Ta₂O₅, Nb₂O₅, AlN, AlNₓ, SiAlₓN_{y}, AlNₓ/SiAlₓN_{y}, Si₃N₄, AlOₓN_{y}, SiOₓN_{y}, SiN_{y}, SiNₓ:H_{y}, HfO₂, TiO₂, ZrO₂, Y₂O₃, Al₂O₃, MoO₃, diamond-like carbon, or combinations thereof. Exemplary materials used in the scratch resistant layer 150 may include an inorganic carbide, nitride, oxide, diamond-like material, or combinations thereof. Examples of suitable materials for the scratch resistant layer 150 include metal oxides, metal nitrides, metal oxynitrides, metal carbides, metal oxycarbides, and/or combinations thereof. Exemplary metals include B, Al, Si, Ti, V, Cr, Y, Zr, Nb, Mo, Sn, Hf, Ta and W. Specific examples of materials that may be utilized in the scratch resistant layer 150 may include Al₂O₃, AlN, AlOₓN_{y}, Si₃N₄, SiOₓN_{y}, SiᵤAlᵥOₓN_{y}, diamond, diamond-like carbon, SiₓC_{y}, SiₓO_{y}C_{z}, ZrO₂, TiOₓN_{y}, and combinations thereof. In some implementations, the scratch resistant layer 150 may include AlOₓN_{y}, Si₃N₄, SiN_{y}, SiOₓN_{y}, and combinations thereof.

Each of the scratch resistant layers 150, as shown in exemplary form in the cover article 100 depicted in FIGS. 1A and 1B, may be relatively thick as compared with other layers (e.g., low RI layers 130A, high RI layers 130B, capping layer 131, etc.) such as greater than or equal to about 200 nm, 250 nm, 300 nm, 325 nm, 350 nm, 375 nm, 400 nm, 425 nm, 450 nm, 475 nm, 500 nm, 525 nm, 550 nm, 575 nm, 600 nm, 700 nm, 800 nm, 900 nm, 1 micron, 2 microns, 3 microns, 4 microns, 5 microns, 6 microns, 7 microns, or even 8 microns. For example, a scratch resistant layer 150 may have a thickness from about 200 nm to about 10 microns, from about 200 nm to about 5 microns, from about 250 nm to about 10 microns, from about 250 nm to about 5 microns, from about 250 nm to about 2.5 microns, from about 500 nm to about 10 microns, from about 500 nm to 7500 nm, from about 500 nm to about 6000 nm, from about 500 nm to about 5000 nm, and all thickness levels and ranges between the foregoing ranges. In other implementations, the scratch resistant layer 150 may have a thickness from about 200 nm to about 10,000 nm, from about 200 nm to about 3000 nm, or from about 500 nm to about 2500 nm.

As shown in FIGS. 1A and 1B, and outlined above, the cover articles 100 of the disclosure include an optical structure 120 comprising an optical coating 130. In implementations, the optical coating 130 includes one or more of an outer structure 130a and an inner structure 130b. Each of the outer and inner structures 130a, 130b of the optical coating 130 includes a plurality of alternating low and high refractive index (RI) layers, 130A and 130B, respectively. According to embodiments, each of the outer and inner structures 130a and 130b includes a period 132 of two or more layers, such as the low RI layer 130A and high RI layer 130B (see FIG. 1A), or a high RI layer 130B and a low RI layer 130A. Further, each of the outer and inner structures 130a and 130b of the optical coating 130 may include a plurality of periods 132, such as 1 to 30 periods, 1 to 25 periods, 1 to 20 periods, and all periods within the foregoing ranges. In addition, the number of periods 132, the number of layers of the outer and inner structures 130a and 130b, and/or the number of layers within a given period 132 can differ or they may be the same. Further, in some implementations, the total amount of layers making up the plurality of alternating low RI and high RI layers 130A and 130B and the scratch resistant layer 150 may range from 2 to 50 layers, 3 to 50 layers, 4 to 50 layers, 5 to 50 layers, 6 to 50 layers, 6 to 40 layers, 6 to 30 layers, 6 to 28 layers, 6 to 26 layers, 6 to 24 layers, 6 to 22 layer, 6 to 20 layers, 6 to 18 layers, 6 to 16 layers, and 6 to 14 layers, and all ranges of layers and amounts of layers between the foregoing values.

As an example, with regard to the cover articles 100 depicted in FIGS. 1A and 1, the period 132 of the outer or inner structures 130a, 130b may include a successive low RI layer 130A and a high RI layer 130B (see FIG. 1A) or a successive high RI layer 130B and a low RI layer 130A (see FIG. 1i). When a plurality of periods is included in either or both of the outer and inner structures 130a and 130b, the low RI layers 130A (designated as “L”) and the high RI layers 130B (designated as “H”) can alternate in the following sequence of layers: L/H/L/H . . . or H/L/H/L . . . , such that the low RI layers 130A and the high RI layers 130B alternate along the physical thickness of the outer and inner structures 130a, 130b of the optical coating 130. Further, the scratch resistant layer 150 of the optical structure 120, as typically comprising a high RI material, can be included in a period 132 with an adjacent low RI layer 130A.

In an exemplary implementation of the cover article 100, as shown in FIG. 1A, the number of periods 132 of the outer and inner structures 130a and 130b of the optical coating 130 can be configured with a total of six (6) periods 132. In particular, the outer structure 130a includes at least five (5) layers (e.g., two (2) periods 132 of alternating low RI and high RI layers 130A, 130B plus a capping layer 131) and the inner structure 130b includes at least seven (7) layers (e.g., four (4) periods 132 of eight (8) layers, alternating low RI and high RI layers 130A, 130B and an alternating low RI layer 130A and scratch resistant layer 150). That is, the inner structure 130b includes a low RI layer 130A directly on the primary surface 112 of the substrate 110. Further, in this implementation of the cover article 100, the optical structure 120 includes a capping layer 131 (similar in structure and thickness to a low RI layer 130A) over the outer structure 130a; and a scratch resistant layer 150 between the outer and inner structures 130a and 130b.

In another exemplary implementation of the cover article 100, as shown in FIG. 1B, the number of periods 132 of the outer and inner structures 130a and 130b of the optical coating 130 can be configured with a total of six (6) periods 132. In particular, the outer structure 130a includes at least five (5) layers (e.g., three (3) periods 132 inclusive of the scratch resistant layer 150 and a low RI layer 130A, an alternating high RI layer and low RI layer 130B, 130A, and an alternating high RI layer 130B and a capping layer 131) and the inner structure 130b includes at least six (6) layers (e.g., three (3) periods 132 of six (6) layers, alternating high RI and low RI layers 130B, 130A). That is, the inner structure 130b includes a low RI layer 130A directly on the primary surface 112 of the substrate 110. Further, in this implementation of the cover article 100, the capping layer 131 is similar in structure and thickness to a low RI layer 130A and the scratch resistant layer 150 is between the outer and inner structures 130a and 130b of the optical coating 130.

According to embodiments of the cover article 100, exemplary designs of the cover article shown in FIG. 1B are detailed below in Table 1. In these four (4) designs, the configurations of the optical structure 120, optical coating 130, and outer and inner structures 130a and 130b are similar in design with a high RI layer 130B disposed directly on the substrate 110. Further, the scratch resistant layer 150 employed in these designs has the same composition (i.e., SiOₓN_{y}) with varying thicknesses (e.g., 500 to 2000 nm). Further, in each configuration, a functional coating 140 is an easy-to-clean (ETC) coating comprising a fluorine-containing material having a thickness from about 5 to 20 nm.

TABLE 1
Exemplary configurations of the cover article depicted in FIG. 1B

| | | | Thickness (nm) | | | |
|---|---|---|---|---|---|---|
| | | | Config. | Config. | Config. | Config. |
| | Layer | Material | 1 | 2 | 3 | 4 |
| 120 | 140 | ETC | 5~20 | 5~20 | 5~20 | 5~20 |
| (130a + | 131 | SiO₂ | 80 | 90 | 100 | 90 |
| 150 + | 130B | SiOₓN_{y} | 140 | 140 | 40 | 100 |
| 130b) | 130A | SiO₂ | 20 | 20 | 180 | 15 |
| | 130B | SiOₓN_{y} | 40 | 40 | 150 | 40 |
| | 130A | SiO₂ | 10 | 10 | 10 | 20 |
| | 150 | SiOₓN_{y} | 500 | 2000 | 1000 | 2000 |
| | 130A | SiO₂ | 10 | 10 | 10 | 10 |
| | 130B | SiOₓN_{y} | 45 | 45 | 45 | 45 |
| | 130A | SiO₂ | 30 | 30 | 30 | 30 |
| | 130B | SiOₓN_{y} | 25 | 25 | 25 | 25 |
| | 130A | SiO₂ | 50 | 50 | 50 | 50 |
| | 130B | SiOₓN_{y} | 10 | 10 | 8 | 8 |
| | 110 | Substrate | | | | |

According to some embodiments of the cover article 100 depicted in FIGS. 1A and 1, the outermost capping layer 131 of the optical structure 120 has a functional coating 140 disposed thereon. In some embodiments, the functional coating 140 (e.g., an easy-to-clean coating 140) is disposed on the outer surface 120a of the optical coating 130. In some implementations of the cover article 100, each high RI layer 130B of the optical structure 120, along with the outer and inner structures 130a, 130b, comprises a nitride, a silicon-containing nitride (e.g., SiNₓ, Si₃N₄), an oxynitride, or a silicon-containing oxynitride (e.g., SiAlₓO_{y}N_{z} or SiOₓN_{y}). Further, according to some embodiments, each low RI layer 130A of the optical structure 120, along with the outer and inner structures 130a, 130b, comprises an oxide or a silicon-containing oxide (e.g., SiO₂, SiOₓ or SiO₂ as doped with Al, N or F).

In one or more embodiments of the cover article 100 depicted in FIGS. 1A and 1B, the term “low RI”, when used with the low RI layers 130A and/or capping layer 131, includes a refractive index range from about 1.3 to about 1.7 or 1.75. In one or more embodiments, the term “high RI”, when used with the high RI layers 130B and/or scratch resistant layer 150, includes a refractive index range from about 1.7 to about 2.5 (e.g., about 1.85 or greater). In some embodiments, the ranges for low RI and/or high RI may overlap; however, in most instances, the layers of each of the outer and inner structures 130a and 130b of the optical coating 130 of the optical structure 120 have the general relationship regarding RI of: low RI<high RI. In one or more embodiments, the difference in the refractive index of each of the low RI layers 130A (and/or capping layer 131) and the high RI layers 130B (and/or scratch resistant layer 150) may be about 0.01 or greater, about 0.05 or greater, about 0.1 or greater, or even about 0.2 or greater.

Example materials suitable for use in the outer and inner structures 130a and 130b of the optical coating 130 of the optical structure 120 of the cover article 100 depicted in FIGS. 1A and 1B include, without limitation, SiO₂, SiOₓ, Al₂O₃, SiAlₓO_{y}, GeO₂, SiO, AlOₓN_{y}, AlN, AlNₓ, SiAlₓN_{y}, SiNₓ, SiOₓN_{y}, SiAlₓO_{y}N_{z}, Ta₂O₅, Nb₂O₅, TiO₂, ZrO₂, TiN, MgO, MgF₂, BaF₂, CaF₂, SnO₂, HfO₂, Y₂O₃, MoO₃, DyF₃, YbF₃, YF₃, CeF₃, diamond-like carbon and combinations thereof some examples of suitable materials for use in a low RI layer 130A include, without limitation, SiO₂, SiOₓ, Al₂O₃, SiAlₓO_{y}, GeO₂, SiO, AlOₓN_{y}, SiOₓN_{y}, SiAlₓO_{y}N_{z}, MgO, MgAlₓO_{y}, MgF₂, BaF₂, CaF₂, DyF₃, YbF₃, YF₃, and CeF₃. In some implementations of the cover article 100, each of its low RI layers 130A includes a silicon-containing oxide (e.g., SiO₂ or SiOₓ). The nitrogen content of the materials for use in a low RI layer 130A may be minimized (e.g., in materials such as Al₂O₃ and MgAlₓO_{y}). Some examples of suitable materials for use in a high RI layer 130B include, without limitation, SiAlₓO_{y}N_{z}, Ta₂O₅, Nb₂O₅, Nb₂O, AlN, AlNₓ, SiAlₓN_{y}, AlNₓ/SiAlₓN_{y}, Si₃N₄, AlOₓN_{y}, SiOₓN_{y}, SiN_{y}, SiNₓ:H_{y}, HfO₂, TiO₂, ZrO₂, Y₂O₃, Al₂O₃, MoO₃, and diamond-like carbon. According to some implementations, each high RI layer 130B of the outer and inner structures 130a, 130b includes a silicon-containing nitride or a silicon-containing oxynitride (e.g., Si₃N₄, SiN_{y}, or SiOₓN_{y}). In one or more embodiments, each of the high RI layers 130B may have high hardness (e.g., hardness of greater than 8 GPa), and the high RI materials listed above may comprise high hardness and/or scratch resistance.

The oxygen content of the materials for the high RI layer 130B may be minimized, especially in SiNₓ materials. Further, exemplary SiOₓN_{y} high RI materials may comprise from about 0 atom % to about 20 atom % oxygen, or from about 5 atom % to about 15 atom % oxygen, while including 30 atom % to about 50 atom % nitrogen. The foregoing materials may be hydrogenated up to about 30% by weight. Where a material having a medium refractive index is desired as a medium RI layer, some embodiments may utilize AlN and/or SiOₓN_{y}. It should be understood that a scratch resistant layer 150 may comprise any of the materials disclosed as suitable for use in a high RI layer 130B.

In one or more embodiments of the cover article 100, the optical structure 120 includes a scratch resistant layer 150 that can be integrated as a high RI layer 130B, and one or more low RI layers 130A, high RI layers 130B, and/or a capping layer 131 may be positioned over the scratch resistant layer 150. Also, with regard to the scratch resistant layer 150, as shown in FIGS. 1A and 1B, the functional coating 140 is generally positioned over the layer 150. The scratch resistant layer 150 may be alternately defined as the thickest high RI layer 130B in the overall optical structure 120 and/or in the outer and the inner structures 130a, 130b of the optical coating 130. Without being bound by theory, it is believed that the cover article 100 may exhibit increased hardness at indentation depths when a relatively thin amount of material is deposited over the scratch resistant layer 150. However, the inclusion of low RI and high RI layers 130A, 130B over the scratch resistant layer 150 may enhance the optical properties of the cover article 100.

In one or more embodiments, the cover article 100 depicted in FIGS. 1A and 1B includes one or more functional coatings 140 disposed on the outer surface 120a of optical coating 130, typically the outer surface 120a of the outer structure 130a. In one or more embodiments, the functional coating 140 includes an easy-to-clean coating. An example of a suitable easy-to-clean coating is described in U. S. Patent Application Publication No. 2014/0113083, published on Apr. 24, 2014, entitled “Process for Making of Glass Articles with Optical and Easy-to-Clean Coatings”, which is incorporated herein in its entirety by reference. In implementations of the cover article 100, the functional coating 140 is an easy-to-clean coating that comprises a fluorine-containing material, e.g., a fluorinated silane. According to some embodiments, the functional coating 140 is an easy-to-clean coating that comprises perfluoro-polyethers (PFPEs) with an alkoxysilane at the end. For example, the functional coating 140 can be an easy-to-clean coating comprising a silane-modified PFPE with a silane functional group for bonding to the outer surface 120a of the optical coating 130. According to some embodiments, the easy-to-clean coating of the functional coating 140 is made through one or more suitable processes, as understood by those skilled in the field of this disclosure, e.g., dip coating, spin coating, spray coating, and physical vapor deposition.

In implementations of the cover article 100, the functional coating 140 (e.g., an easy-to-clean coating) has a thickness in the range from about 2 nm to 75 nm, from about 5 nm to about 50 nm or from about 5 nm to 25 nm. The easy-to-clean coating may alternately or additionally comprise a low-friction coating or surface treatment. Exemplary low-friction coating materials may include diamond-like carbon, silanes (e.g., fluorosilanes), phosphonates, alkenes, and alkynes.

In some embodiments, the functional coating 140 (e.g., an easy-to-clean coating) may have a thickness in the range from about 1 nm to about 40 nm, from about 1 nm to about 30 nm, from about 1 nm to about 25 nm, from about 1 nm to about 20 nm, from about 1 nm to about 15 nm, from about 1 nm to about 10 nm, from about 5 nm to about 50 nm, from about 10 nm to about 50 nm, from about 15 nm to about 50 nm, from about 7 nm to about 20 nm, from about 7 nm to about 15 nm, from about 7 nm to about 12 nm, from about 7 nm to about 10 nm, from about 1 nm to about 90 nm, from about 5 nm to about 90 nm, from about 10 nm to about 90 nm, or from about 5 nm to about 100 nm, and all ranges and sub-ranges therebetween.

The functional coating 140 may additionally include a scratch resistant layer or layers which comprise any of the materials disclosed as being suitable for use in the scratch resistant layer 150. In some embodiments, the functional coating 140 includes a combination of easy-to-clean material and scratch resistant material. In one example, the combination includes an easy-to-clean material and diamond-like carbon. Such a functional coating 140 may have a thickness in the range from about 5 nm to about 20 nm. The constituents of the functional coating 140 may be provided in separate layers. For example, the diamond-like carbon may be disposed as a first layer and the easy-to-clean material can be disposed as a second layer on the first layer of diamond-like carbon. The thicknesses of the first layer and the second layer may be in the ranges provided above for the additional coating. For example, the first layer of diamond-like carbon may have a thickness of about 1 nm to about 20 nm or from about 4 nm to about 15 nm (or more specifically about 10 nm) and the second layer of easy-to-clean material may have a thickness of about 1 nm to about 10 nm (or more specifically about 6 nm). The diamond-like coating may include tetrahedral amorphous carbon (Ta—C), Ta—C:H, and/or a-C—H.

According to embodiments of the cover article 100 depicted in FIGS. 1A and 1B, each of the high RI layers 130B of the outer and inner structures 130a, 130b of the optical coating 130 of the optical structure 120 can have a physical thickness that ranges from about 5 nm to 2000 nm, about 5 nm to 1500 nm, about 5 nm to 1000 nm, and all thicknesses and ranges of thickness between these values. For example, these high RI layers 130B can have a physical thickness of 5 nm, 10 nm, 20 nm, 30 nm, 40 nm, 50 nm, 60 nm, 70 nm, 80 nm, 90 nm, 100 nm, 250 nm, 500 nm, 750 nm, 1000 nm, 1250 nm, 1500 nm, 1750 nm, 2000 nm and all thickness values between these levels. Further, each of the high RI layers 130B of the inner structure 130b can have a physical thickness that ranges from about 5 nm to 500 nm, about 5 nm to 400 nm, about 5 nm to 300 nm, and all thicknesses and ranges of thickness between these values. As an example, each of these high RI layers 130B can have a physical thickness of 5 nm, 10 nm, 20 nm, 30 nm, 40 nm, 50 nm, 60 nm, 70 nm, 80 nm, 90 nm, 100 nm, 200 nm, 300 nm, 400 nm, 500 nm, and all thickness values between these levels. In addition, according to some embodiments of the cover article 100 depicted in FIGS. 1A and 1B, each of the low RI layers 130A of the outer and inner structures 130a, 130b can have a physical thickness from about 5 nm to 300 nm, about 5 nm to 250 nm, about 5 nm to 200 nm, and all thicknesses and ranges of thickness between these values. For example, each of these low RI layers 130A can have a physical thickness of 5 nm, 10 nm, 20 nm, 30 nm, 40 nm, 50 nm, 60 nm, 70 nm, 80 nm, 90 nm, 100 nm, 150 nm, 200 nm, 250 nm, 300 nm, and all thickness values between these levels.

As noted earlier, the cover articles 100 include a functional coating 140 (e.g., an easy-to-clean coating comprising a fluorine-containing material) with high durability. Notably, the durability of the functional coating 140 of the cover articles 100 of the disclosure can be influenced by the surface roughness of their optical structure 120 and/or optical coating 130. For example, implementations of the cover articles 100 are configured such that the outer surface 120a of the optical coating 130 of the optical structure 120 possesses a surface roughness (Ra) of less than 1.5 nm, less than 1.2 nm, or even less than 1.0 nm. According to some embodiments, the surface roughness (Ra) of the outer surface 120a of the optical coating 130 of the optical structure 120 is 1.45 nm, 1.40 nm, 1.35 nm, 1.30 nm, 1.25 nm, 1.20 nm, 1.15 nm, 1.10 nm, 1.05 nm, 1.0 nm, 0.9 nm, 0.8 nm, 0.7 nm, 0.6 nm, 0.5 nm, and all surface roughness (Ra) values between the foregoing ranges and sub-ranges.

According to embodiments of the cover articles 100 of the disclosure, configuring or otherwise adjusting the outer surface 120a of the optical coating 130 to be smooth with a low surface roughness improves the durability of the functional coating 140 disposed on the outer surface 120a, as measured or evaluated using the Steel Wool Abrasion Test. Without being bound by theory, the smoother outer surface 120a of the optical coating 130 tends to improve the adhesion between the functional coating 140 (e.g., an easy-to-clean coating comprising a fluorine-containing material) and the optical coating 130, optical structure 120 and the underlying substrate 110, thus improving the durability of the functional coating 140 from a wear standpoint, as measured by the Steel Wool Abrasion Test.

According to embodiments of the cover articles 100 of the disclosure, the functional coating 140 (e.g., an easy-to-clean coating comprising a fluorine-containing material) can exhibit a water contact angle of greater than 95° after 1000 cycles, 2000 cycles, or even 3000 cycles, in a Steel Wool Abrasion Test (see FIGS. 3A and 3B, and corresponding description later in the disclosure). In some aspects, the functional coating 140 of the cover article 100 is particularly durable with a water contact angle of greater than 100°, or even 105°, after 1000 cycles, 2000 cycles, or even 3000 cycles, in a Steel Wool Abrasion Test. For example, the functional coating 140 can exhibit a contact angle of greater than 95°, 100°, or 105°, after being subjected to 1000 cycles, 1250 cycles, 1500 cycles, 1750 cycles, 2000 cycles, 2250 cycles, 2500 cycles, 2750 cycled, or even 3000 cycles, and all contact angles and cycles between the foregoing ranges, in a Steel Wool Abrasion Test.

The substrate 110 of the cover article 100 depicted in FIGS. 1A and 1B may include an inorganic material with amorphous and crystalline portions. The substrate 110 may be formed from man-made materials and/or naturally occurring materials (e.g., quartz). In some specific embodiments, the substrate 110 may specifically exclude polymeric, plastic and/or metal substrates. The substrate 110 may be characterized as an alkali-including substrate (i.e., the substrate includes one or more alkalis). In some implementations, the substrate 110 comprises a glass composition, a glass-ceramic composition, or a ceramic composition. In one or more embodiments, the substrate 110 exhibits a refractive index in the range from about 1.5 to about 1.6.

Suitable substrates 110 may exhibit an elastic modulus (or Young's modulus) in the range from about 60 GPa to about 130 GPa. In some instances, the elastic modulus of the substrate 110 may be in the range from about 70 GPa to about 120 GPa, from about 80 GPa to about 110 GPa, from about 80 GPa to about 100 GPa, from about 80 GPa to about 90 GPa, from about 85 GPa to about 110 GPa, from about 85 GPa to about 105 GPa, from about 85 GPa to about 100 GPa, from about 85 GPa to about 95 GPa, and all ranges and sub-ranges therebetween (e.g., −103 GPa). In some implementations, the elastic modulus of the substrate 110 may be greater than 85 GPa, greater than 90 GPa, greater than 95 GPa, or even greater than 100 GPa. In some examples, Young's modulus may be measured by sonic resonance (ASTME1875), resonant ultrasound spectroscopy, or nanoindentation using Berkovich indenters.

In one or more embodiments, the substrate 110 may include glass, which may be strengthened or non-strengthened. Examples of suitable glass include soda lime glass, alkali aluminosilicate glass, alkali containing borosilicate glass and alkali aluminoborosilicate glass. In some variants, the glass may be free of lithia. In one or more alternative embodiments, the substrate 110 may include crystalline substrates such as glass-ceramic substrates (which may be strengthened or non-strengthened) or may include a single crystal structure, such as sapphire. In one or more specific embodiments, the substrate 110 includes an amorphous base (e.g., glass) and a crystalline cladding (e.g., a sapphire layer, a polycrystalline alumina layer and/or or a spinel (MgAl₂O₄) layer).

In one or more embodiments, the substrate 110 includes one or more glass-ceramic materials and may be strengthened or non-strengthened. In one or more embodiments, the substrates 110 may comprise one or more crystalline phases such as lithium disilicate, lithium metasilicate, petalite, beta quartz, and/or beta spodumene, as potentially combined with residual glass in the structure. In an embodiment, the substrate 110 comprises a disilicate phase. In another implementation, the substrate 110 comprises a disilicate phase and a petalite phase. According to an embodiment, the substrate 110 has a crystallinity of at least 40% by weight. In some implementations, the substrate 110 has a crystallinity of at least about 40%, 45%, 50%, 55%, 60%, 65%, 70%, 75%, 80%, 85%, or greater (by weight), with the residual as a glass phase.

According to implementations, the substrate 110 is substantially optically clear, transparent and free from light scattering. In such embodiments, the substrate 110 may exhibit an average light transmittance over the optical wavelength regime of about 80% or greater, about 81% or greater, about 82% or greater, about 83% or greater, about 84% or greater, about 85% or greater, about 86% or greater, about 87% or greater, about 88% or greater, about 89% or greater, about 90% or greater, about 91% or greater, about 92% or greater, about 93% or greater, or even about 94% or greater. In some embodiments, these light reflectance and transmittance values may be a total reflectance or total transmittance (taking into account reflectance or transmittance on both primary surfaces of the substrate 110) or may be observed on a single-side of the substrate 110 (i.e., on the primary surface 112 only, without taking into account the opposite surface 114). Unless otherwise specified, the average reflectance or transmittance of the substrate 110 alone is measured at an incident illumination angle of 0 degrees relative to the primary surface 112 (however, such measurements may be provided at incident illumination angles of 45 degrees or 60 degrees).

The substrate 110 may be provided using a variety of different processes. For instance, where the substrate 110 includes, or is primarily composed of, an amorphous portion or phase such as glass, various forming methods can include float glass processes and down-draw processes such as fusion draw and slot draw.

Once formed, the substrate 110 may be strengthened to form a strengthened substrate. Where the substrate 110 is chemically strengthened by an ion exchange process, the ions in the surface layer of the substrate 110 are replaced by—or exchanged with—larger ions having the same valence or oxidation state. Ion exchange processes are typically carried out by immersing a substrate in a molten salt bath containing the larger ions to be exchanged with the smaller ions in the substrate. It will be appreciated by those skilled in the art that parameters for the ion exchange process, including, but not limited to, bath composition and temperature, immersion time, the number of immersions of the substrate 110 in a salt bath (or baths), use of multiple salt baths, additional steps such as annealing, washing, and the like, are generally determined by the composition of the substrate 110 and the desired compressive stress (CS), depth of compressive stress layer (or depth of layer) of the substrate 110 that result from the strengthening operation. By way of example, ion exchange of alkali metal-containing glass-ceramic or glass substrates may be achieved by immersion in at least one molten bath containing a salt such as, but not limited to, nitrates, sulfates, and chlorides of the larger alkali metal ion. The temperature of the molten salt bath typically is in a range from about 380° C. up to about 530° C., while immersion times range from about 15 minutes up to about 40 hours. However, temperatures and immersion times different from those described above may also be used.

The degree of chemical strengthening achieved by ion exchange may be quantified based on the parameters of central tension (CT), surface CS, depth of compression (DOC) (i.e., the point in the substrate in which the stress state changes from compression to tension), and depth of layer of potassium ions (DOL). Compressive stress (including surface CS) is measured by a surface stress meter (FSM) using commercially available instruments such as the FSM-6000, manufactured by Orihara Industrial Co., Ltd. (Japan). Surface stress measurements rely upon the accurate measurement of the stress optical coefficient (SOC), which is related to the birefringence of the glass-ceramic material. SOC in turn is measured according to Procedure C (Glass Disc Method) described in ASTM standard C770-16, entitled “Standard Test Method for Measurement of Glass Stress-Optical Coefficient,” the contents of which are incorporated herein by reference in their entirety. Refracted near-field (RNF) method or a scattered light polariscope (SCALP) technique may be used to measure the stress profile. When the RNF method is utilized to measure the stress profile, the maximum CT value provided by SCALP is utilized in the RNF method. In particular, the stress profile measured by RNF is force balanced and calibrated to the maximum CT value provided by a SCALP measurement. The RNF method is described in U.S. Pat. No. 8,854,623, issued Oct. 7, 2014, entitled “Systems and Methods for Measuring a Profile Characteristic of a Glass Sample”, which is incorporated herein by reference in its entirety. In particular, the RNF method includes placing the cover article adjacent to a reference block, generating a polarization-switched light beam that is switched between orthogonal polarizations at a rate of between 1 Hz and 50 Hz, measuring an amount of power in the polarization-switched light beam and generating a polarization-switched reference signal, wherein the measured amounts of power in each of the orthogonal polarizations are within 50% of each other. The method further includes transmitting the polarization-switched light beam through the sample and reference block for different depths into the sample, then relaying the transmitted polarization-switched light beam to a signal photodetector using a relay optical system, with the signal photodetector generating a polarization-switched detector signal. The method also includes dividing the detector signal by the reference signal to form a normalized detector signal and determining the profile characteristic of the sample from the normalized detector signal. The maximum CT values are measured using a scattered light polariscope (SCALP) technique known in the art.

In one embodiment of the cover article 100 (see FIGS. 1A and 1B), a strengthened substrate 110 can have a surface CS of 200 MPa or greater, 250 MPa or greater, 300 MPa or greater, or 350 MPa or greater. In another implementation, a strengthened substrate 110 can exhibit a surface compressive stress (CS) of from about 200 MPa to about 600 MPa, from about 200 MPa to about 500 MPa, from about 200 MPa to about 400 MPa, from about 225 MPa to about 400 MPa, from 250 MPa to about 400 MPa, and all CS sub-ranges and values in the foregoing ranges. The strengthened substrate 110 may have a DOL of from 1 μm to 5 μm, from 1 μm to 10 μm, or from 1 μm to 15 μm and/or a central tension (CT) of 50 MPa or greater, 75 MPa or greater, 100 MPa or greater, 125 MPa or greater (e.g., 80 MPa, 90 MPa, or 100 MPa or greater) but less than 250 MPa (e.g., 200 MPa or less, 175 MPa or less, 150 MPa or less, etc.).

The depth of compression (DOC) of the substrate 110 may be from 0.1·(thickness (t) of the substrate) to about 0.25·t, for example from about 0.15·t to about 0.25·t, or from about 0.15·t to about 0.20·t, and all DOC values between the foregoing ranges. For example, the substrate 110 can have a DOC of 20% of the thickness of the substrate, as compared to 15% or less for ion-exchanged glass substrates. In embodiments, the depths of compression for the substrate materials can be from 08% to ˜20% of the thickness of the substrate 110. Note that the foregoing DOC values are as measured from one of the primary surfaces 112 or 114 of the substrate 110. As such, for a substrate 110 with a thickness of 600 μm, the DOC may be 20% of the thickness of the substrate, ˜120 m from each of the primary surfaces 112, 114 of the substrate 110, or 240 μm in total for the entire substrate. In one or more specific embodiments, the strengthened substrate 110 can exhibit one or more of the following mechanical properties: a surface CS of from about 200 MPa to about 400 MPa, a DOL of greater than 30 μm, a DOC of from about 0.08·t to about 0.25·t, and a CT from about 80 MPa to about 200 MPa.

According to embodiments of the disclosure, the substrate 110 (without the optical structure 120 disposed thereon for measurement purposes) can exhibit a maximum hardness of 8.5 GPa or greater, 9 GPa or greater, or 9.5 GPa or greater (or even greater than 10 GPa in some instances), as measured by a Berkovich Hardness Test over an indentation depth range from 100 nm to about 500 nm in the substrate 110. For example, the substrate 110 can exhibit a maximum hardness of 8.5 GPa, 8.75 GPa, 9 GPa, 9.25 GPa, 9.5 GPa, 9.75 GPa, 10 GPa, and higher hardness levels, as measured by a Berkovich Hardness Test over an indentation depth range from 100 nm to about 500 nm in the substrate 110.

Example glasses that can be used in the substrate 110 may include alkali aluminosilicate glass compositions or alkali aluminoborosilicate glass compositions, though other glass compositions are contemplated. Such glass compositions are capable of being chemically strengthened by an ion exchange process. One example glass composition comprises SiO₂, B₂O₃ and Na₂O, where (SiO₂+B₂O₃)≥66 mol. %, and Na₂O≥9 mol. %. In an embodiment, the glass composition includes at least 6 wt. % aluminum oxide. In a further embodiment, the substrate includes a glass composition with one or more alkaline earth oxides, such that a content of alkaline earth oxides is at least 5 wt. %. Suitable glass compositions, in some embodiments, further comprise at least one of K₂O, MgO, and CaO. In a particular embodiment, the glass compositions used in the substrate can comprise 61-75 mol. % SiO2; 7-15 mol. % Al₂O₃; 0-12 mol. % B₂O₃; 9-21 mol. % Na₂O; 0-4 mol. % K₂O; 0-7 mol. % MgO; and 0-3 mol. % CaO.

A further example glass composition suitable for the substrate 110 comprises: 60-70 mol. % SiO₂; 6-14 mol. % Al₂O₃; 0-15 mol. % B₂O₃; 0-15 mol. % Li₂O; 0-20 mol. % Na₂O; 0-10 mol. % K₂O; 0-8 mol. % MgO; 0-10 mol. % CaO; 0-5 mol. % ZrO₂; 0-1 mol. % SnO₂; 0-1 mol. % CeO₂; less than 50 ppm As₂O₃; and less than 50 ppm Sb₂O₃; where 12 mol. % (Li₂O+Na₂O+K₂O)≤20 mol. % and 0 mol. % (MgO+CaO)≤10 mol. %.

A still further example glass composition suitable for the substrate 110 comprises: 63.5-66.5 mol. % SiO₂; 8-12 mol. % Al₂O₃; 0-3 mol. % B₂O₃; 0-5 mol. % Li₂O; 8-18 mol. % Na₂O; 0-5 mol. % K₂O; 1-7 mol. % MgO; 0-2.5 mol. % CaO; 0-3 mol. % ZrO₂; 0.05-0.25 mol. % SnO₂; 0.05-0.5 mol. % CeO₂; less than 50 ppm As₂O₃; and less than 50 ppm Sb₂O₃; where 14 mol. %≤(Li₂O+Na₂O+K₂O)≤18 mol. % and 2 mol. % (MgO+CaO)≤7 mol. %.

In a particular embodiment, an alkali aluminosilicate glass composition suitable for the substrate 110 comprises alumina, at least one alkali metal and, in some embodiments, greater than 50 mol. % SiO₂, in other embodiments at least 58 mol. % SiO₂, and in still other embodiments at least 60 mol. % SiO₂, wherein the ratio (Al₂O₃+B₂O₃)/Σ modifiers (i.e., sum of modifiers) is greater than 1, where in the ratio the components are expressed in mol. % and the modifiers are alkali metal oxides. This glass composition, in particular embodiments, comprises: 58-72 mol. % SiO₂; 9-17 mol. % Al₂O₃; 2-12 mol. % B₂O₃; 8-16 mol. % Na₂O; and 0-4 mol. % K₂O, wherein the ratio (Al₂O₃+B₂O₃)/Σ modifiers (i.e., sum of modifiers) is greater than 1.

In still another embodiment, the substrate 110 may include an alkali aluminosilicate glass composition comprising: 64-68 mol. % SiO₂; 12-16 mol. % Na₂O; 8-12 mol. % Al₂O₃; 0-3 mol. % B₂O₃; 2-5 mol. % K₂O; 4-6 mol. % MgO; and 0-5 mol. % CaO, wherein: 66 mol. %≤SiO₂+B₂O₃+CaO 69 mol. %; Na₂O+K₂O+B₂O₃+MgO+CaO+SrO≥10 mol. %; 5 mol. % MgO+CaO+SrO 8 mol. %; (Na₂O+B₂O₃)—Al₂O₃ 2 mol. %; 2 mol. % Na₂O—Al₂O₃ 6 mol. %; and 4 mol. % (Na₂O+K₂O)—Al₂O₃≤10 mol. %.

In an alternative embodiment, the substrate 110 may comprise an alkali aluminosilicate glass composition comprising: 2 mol. % or more of Al₂O₃ and/or ZrO₂, or 4 mol. % or more of Al₂O₃ and/or ZrO₂.

Where the substrate 110 includes a crystalline substrate, the substrate may include a single crystal, which may include Al₂O₃. Such single crystal substrates are referred to as sapphire. Other suitable materials for a crystalline substrate include polycrystalline alumina layer and/or spinel (MgAl₂O₄).

Optionally, the substrate 110 may be crystalline and include a glass-ceramic substrate, which may be strengthened or non-strengthened. Examples of suitable glass ceramics for the substrate 110 may include Li₂O—Al₂O₃—SiO₂ system (i.e., LAS-System) glass ceramics, MgO—Al₂O₃—SiO₂ system (i.e., MAS-System) glass ceramics, and/or glass ceramics that include a predominant crystal phase including β-quartz solid solution, β-spodumene ss, cordierite, and lithium disilicate. The glass-ceramic substrates may be strengthened using the chemical strengthening processes disclosed herein. In one or more embodiments, MAS-System glass-ceramic substrates may be strengthened in Li₂SO₄ molten salt, whereby an exchange of 2Li⁺ for Mg²⁺ can occur.

The substrate 110 according to one or more embodiments can have a physical thickness ranging from about 100 μm to about 5 mm in various portions of the substrate 110. Example substrate 110 physical thicknesses range from about 100 μm to about 500 μm (e.g., 100, 200, 300, 400 or 500 μm), from about 500 μm to about 1000 μm (e.g., 500, 600, 700, 800, 900 or 1000 μm), and from about 500 μm to about 1500 μm (e.g., 500, 750, 1000, 1250, or 1500 μm), for example. In some implementations, the substrate 110 may have a physical thickness greater than about 1 mm (e.g., about 2, 3, 4, or 5 mm). In one or more specific embodiments, the substrate 110 may have a physical thickness of 2 mm or less, or less than 1 mm. The substrate 110 may be acid polished or otherwise treated to remove or reduce the effect of surface flaws.

With regard to the hardness of the cover articles 100 depicted in FIGS. 1A and 1, typically, in nanoindentation measurement methods (such as by using a Berkovich indenter) where the optical structure 120 is harder than the underlying substrate, the measured hardness may appear to increase initially due to development of the plastic zone at shallow indentation depths (e.g., less than 25 nm or less than 50 nm) and then increases and reaches a maximum value or plateau at deeper indentation depths (e.g., from 50 nm to about 500 nm or 1000 nm). Thereafter, hardness begins to decrease at even deeper indentation depths due to the effect of the underlying substrate. Where a substrate 110 having a greater hardness compared to the optical structure 120 is utilized, the same effect can be seen; however, the hardness increases at deeper indentation depths due to the effect of the underlying substrate.

With further regard to the cover articles 100 depicted in FIGS. 1A and 1B, the indentation depth range and the hardness values at certain indentation depth ranges can be selected to identify a particular hardness response of the optical structure 120, the optical coating 130, and the layers of the outer and inner structures 130a, 130b thereof, described herein, without the effect of the underlying substrate 110. When measuring hardness of the optical structure 120 (when disposed on a substrate 110) with a Berkovich indenter, the region of permanent deformation (plastic zone) of a material is associated with the hardness of the material. During indentation, an elastic stress field extends well beyond this region of permanent deformation. As indentation depth increases, the apparent hardness and modulus are influenced by stress field interactions with the underlying substrate 110. The influence of the substrate 110 on hardness occurs at deeper indentation depths (i.e., typically at depths greater than about 10% of the total thickness of the optical structure 120). Moreover, a further complication is that the hardness response requires a certain minimum load to develop full plasticity during the indentation process. Prior to that certain minimum load, the hardness shows a generally increasing trend.

At small indentation depths (which also may be characterized as small loads) (e.g., up to about 50 nm) in the optical structure 120, the apparent hardness of a material appears to increase dramatically versus indentation depth. This small indentation depth regime does not represent a true metric of hardness but, instead, reflects the development of the aforementioned plastic zone, which is related to the finite radius of curvature of the indenter. At intermediate indentation depths, the apparent hardness approaches maximum levels. At deeper indentation depths, the influence of the substrate 110 becomes more pronounced as the indentation depths increase. Hardness may begin to drop dramatically once the indentation depth exceeds about 30% of the optical coating thickness.

In one or more embodiments, the cover article 100 and/or the optical structure 120, as depicted in FIGS. 1A and 1B, may exhibit a maximum hardness of about 10 GPa or greater, about 11 GPa or greater, or about 12 GPa or greater, 13 GPa or greater, or 14 GPa or greater, as measured from the outer surface 120a of the optical structure 120 by a Berkovich Indenter Hardness Test along an indentation depth of 50 nm or greater, from about 100 nm to about 500 nm, or along an indentation depth from about 100 nm to about 900 nm. For example, the cover article 100 and/or its optical structure 120 can exhibit a maximum hardness of 10 GPa, 11 GPa, 12 GPa, 13 GPa, 14 GPa, 15 GPa, 16 GPa, 17 GPa, 18 GPa, 19 GPa, 20 GPa, or greater, as measured from the outer surface 120a of the optical structure 120 by a Berkovich Indenter Hardness Test along an indentation depth of 50 nm or greater. In some implementations, the maximum hardness of the cover article 100 and/or the optical structure 120 is greater than 10 GPa, 11 GPa, 12 GPa, 13 GPa, 14 GPa, 15 GPa, 16 GPa, 17 GPa, 18 GPa, or 19 GPa, at an indentation depth of 50 nm or 100 nm. In some implementations, the maximum hardness of the cover article 100 and/or optical structure 120 is greater than 10 GPa, 12 GPa, 14 GPa, 16 GPa, 17 GPa, 18 GPa, or 19 GPa, at an indentation depth of 500 nm.

With further regard to the hardness of the cover articles 100 and/or optical structures 120 depicted in FIGS. 1A and 1i, the hardness of the material of a high RI layer 130B and/or scratch resistant layer 150 may be characterized specifically. In some embodiments, the maximum hardness of the high RI layer 130B and/or the scratch resistant layers 150, as measured by the Berkovich Indenter Hardness Test, may be about 10 GPa or greater, about 12 GPa or greater, about 15 GPa or greater, about 18 GPa or greater, or even about 20 GPa or greater. The hardness of a given layer (e.g., high RI layer 130B) may be measured by analyzing a cover article 100 where the layer measured is the uppermost layer in the optical structure 120. If the layer to be measured for hardness is a buried layer, its hardness may be measured by producing a transparent article which does not include the overlying layers and subsequently testing the article for hardness. Such measured hardness values may be exhibited by the cover article 100, optical structure 120, optical coating 130, outer and inner structures 130a, 130b, high RI layer 130B, and/or scratch resistant layers 150, along an indentation depth of about 50 nm or greater or about 100 nm or greater, and may be sustained above a certain hardness value for a continuous indentation depth range.

According to embodiments, the cover articles 100 depicted in FIGS. 1A and 1B may exhibit an average two-sided or two-surface (i.e., through both primary surfaces 112, 114 of the substrate 110) photopic transmittance, or average transmittance in the visible spectrum over an optical wavelength regime from 400 to 700 nm, or from 450 to 650 nm, of about 80% or greater, about 85% or greater, about 90% or greater, about 91% or greater, about 92% or greater, about 93% or greater, or even about 94% or greater at normal incidence, from 0 to 10 degrees, from 0 to 20 degrees, from 5 to 20 degrees, from 0 to 30 degrees, from 0 to 40 degrees, from 0 to 50 degrees, or even from 0 to 60 degrees.

According to some implementations, the cover articles 100 depicted in FIGS. 1A and 1B may exhibit a transmitted color with a D65 illuminant, as given by (a*2+b*²), of less than 4, less than 3.5, less than 3, less than 2.5, less than 2, less than 1.5, or even less than 1, as measured at normal incidence, from 0 to 10 degrees, or over all incidence angles from 0 to 90 degrees. For example, the cover articles 100 can exhibit a transmitted color of less than 4, 3.75, 3.5, 3.25, 3, 2.75, 2.5, 2.25, 2, 1.9, 1.8, 1.7, 1.6, 1.5, 1.4, 1.3, 1.2, 1.1, 1.0, 0.9, 0.8, 0.7, 0.6, 0.5, or even lower, as measured at normal incidence, from 0 to 10 degrees, from 5 to 20 degrees, or over all incidence angles from 0 to 90 degrees.

According to embodiments, the cover articles 100 depicted in FIGS. 1A and 1B may exhibit an average single-sided or first-surface (i.e., through one of the primary surfaces 112, 114 of the substrate 110) photopic reflectance, or average reflectance over an optical wavelength regime from 400 to 700 nm, or from 450 to 650 nm, through one or both primary surfaces of the substrate 110 (i.e., first-surface or a two-surface reflectance), of less than 20%, less than about 15%, less than about 13%, less than about 12%, less than about 10%, less than about 8%, less than about 6%, less than about 4%, less than about 2%, or even less than 1%, at normal incidence, from 0 to 10 degrees, or from 5 to 20 degrees. For example, the cover articles 100 can exhibit a first-surface average photopic reflectance of less than 20%, less than 15%, less than 10%, less than 5%, less than 2%, less than 10%, or even less than 0.8%, as measured at incident angles from 0 to 10 degrees, or from 5 to 20 degrees.

According to some implementations, the cover articles 100 depicted in FIGS. 1A and 1B may exhibit a first-surface (i.e., through one of the primary surfaces 112, 114 of the substrate 110), reflected color with a D65 illuminant, as given by (a*2+b*²), of less than 10, less than 8, less than 6, less than 4, less than 3, or even less than 2, as measured at normal incidence, from 0 to 10 degrees, from 5 to 20 degrees, or over all incidence angles from 0 to 90 degrees. For example, the cover articles 100 can exhibit a reflected color of less than 10, 9, 8, 7, 6, 5, 4, 3.75, 3.5, 3.25, 3, 2.75, 2.5, 2.25, 2, 1.9, 1.8, 1.7, 1.6, 1.5, 1.4, 1.3, 1.2, 1.1, 1, or even lower, as measured at normal incidence, from 0 to 10 degrees, or over all incidence angles from 0 to 90 degrees.

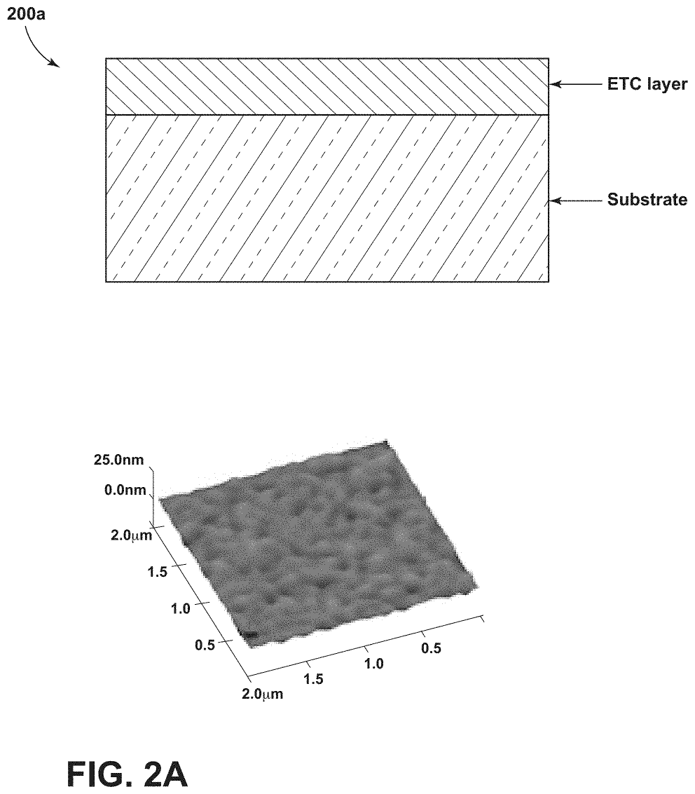

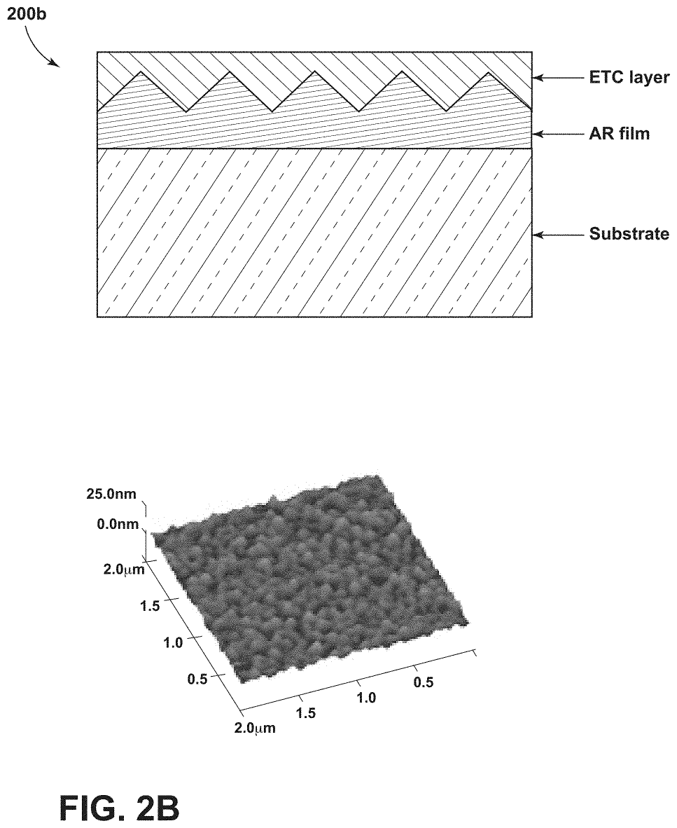

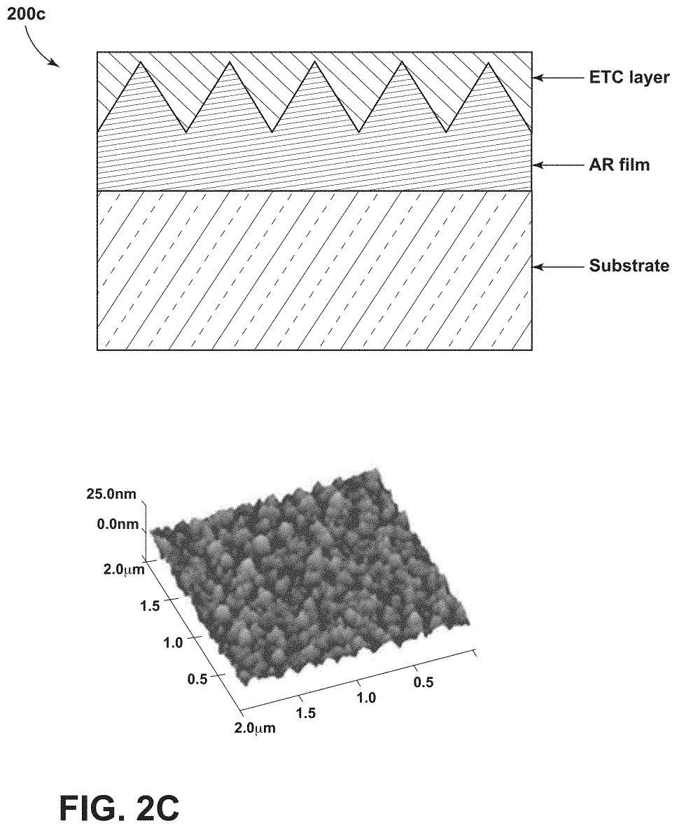

Referring now to FIGS. 2A-2C, cross-sectional schematics are provided of an easy-to-clean (ETC) coating on a substrate and an easy-to-clean coating on each of two antireflective films having different surface roughness levels over a substrate. In FIG. 2A, a comparative cover article 200a (Comp. Ex. 1A) is depicted with an ETC coating disposed directly on the primary surface of a strengthened glass substrate (e.g., Corning® Gorilla Glass®), the primary surface having a surface roughness (Ra) of about 0.2 to 0.5 nm. In FIG. 2B, a comparative cover article 200b (Comp. Ex. 1B) is depicted with an ETC coating disposed directly on the outer surface of an antireflective (AR) film, which is disposed on a primary surface of a strengthened glass substrate. Further, the outer surface of the AR film (thickness of ˜0.5 μm) has a surface roughness (Ra) of about 1.5 nm. In FIG. 2C, a comparative cover article 200c (Comp. Ex. 1C) is depicted with an ETC coating disposed directly on the outer surface of an antireflective (AR) film, which is disposed on a primary surface of a strengthened glass substrate. Further, the outer surface of the AR film (thickness of ˜2.0 μm) has a surface roughness (Ra) of about 2.5 nm.

Referring again to FIGS. 2A-2C, the durability of the ETC coating of the comparative cover article 200a far exceeds that of the comparative cover articles 200b, 200c. Without being bound by theory, it is believed that the ETC coating of the comparative article 200a exhibits superior durability over the ETC coatings of comparative articles 200b, 200c because the surface in which the ETC coating is bonded to in the comparative article 200a is much smoother than the bonding surface of the ETC coatings of comparative articles 200b, 200c. These observations are consistent with the approach employed by the cover articles 100 of the disclosure, in which the smoothness of the outer surface 120a of the optical coating 130 is maximized to improve the durability of the functional coating 140 (e.g., an ETC coating).

Referring now to FIG. 3A, a cross-sectional schematic is provided of an apparatus 300a for conducting a Steel Wool Abrasion Test on a cover article, e.g., cover articles 100 of the disclosure (see also FIGS. 1A and 1i, and corresponding disclosure). As used herein, the “Steel Wool Abrasion Test” or “Steel Wool Test” interchangeably reference a test that employs a testing apparatus 300a to determine the durability of a functional coating 140 (e.g., an ETC coating) disposed on the optical structure 120 (e.g., an outer surface 120a of the optical coating 130 shown in FIGS. 1A and 1B) and over a substrate 110 of the cover articles 100 of the disclosure. At the beginning of a Steel Wool Abrasion Test, a water contact angle for a water drop 320 is measured on the cover article 100 one or more times to obtain a reliable initial water contact angle 330 (see FIG. 3B). These water contact angle measurements can be conducted using a Kruss GmbH DSA100 drop shape analyzer or similar instrument. After the initial water contact angle is measured, a pad 310 of Bonstar #0000 steel wool is affixed to an arm of a Taber® Industries 5750 linear abrader instrument (see FIG. 3A). The steel wool pad 310 is then allowed to make contact with the cover article 100 (on the ETC coating 140) under a load of 1 kg and set to reciprocate at 60 cycles/min. The average contact angle 330 is then measured on the sample after 1000 cycles, 1500 cycles, 2000 cycles, 3000 cycles, 3500 cycles and/or another specified duration.

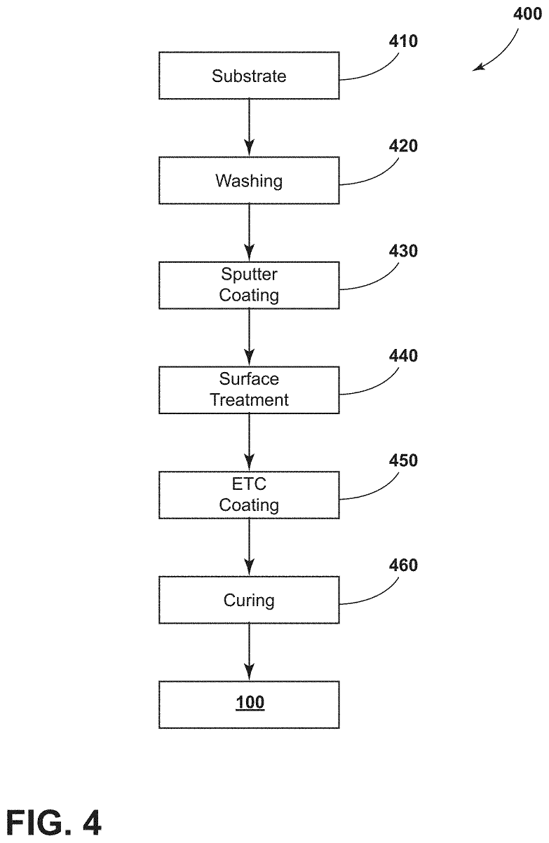

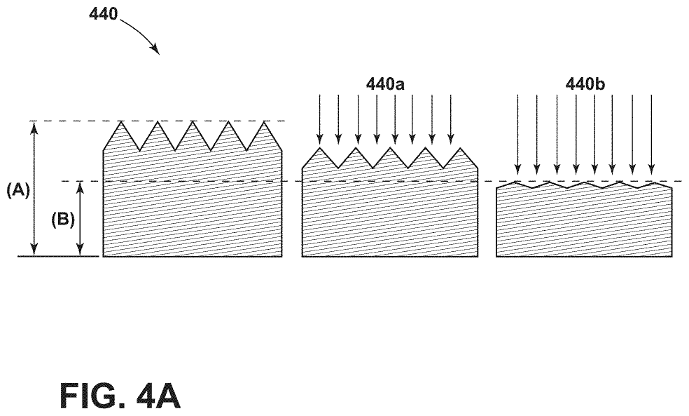

Referring now to FIG. 4, a flow chart schematic is provided of a method 400 of making a cover article 100 (see FIGS. 1A and 1B, and corresponding description), according to an embodiment of the disclosure. According to an embodiment, the method 400 of making a cover article (e.g., cover articles 100) includes a step 410 of providing a substrate (e.g., substrate 110) having a primary surface. The method also includes an optional step 420 of washing the primary surface of the substrate using a suitable process in view of the composition of the substrate (e.g., an aqueous cleaning process employing deionized water). The method 400 also includes a step 430 of depositing an optical structure (e.g., optical structure 120) on the primary surface of the substrate. More specifically, step 430 can be employed to deposit the various layers that make up the optical structure 120, including the scratch resistant layer 150, optical coating 130 and capping layer 131. Various sputtering processes can be employed in step 430, as understood by those skilled in the field of the disclosure, including plasma-enhanced chemical vapor deposition (PECVD), a reactive sputtering process, chemical vapor deposition (CVD), physical vapor deposition (PVD), etc. Ultimately, step 430 is conducted to form the optical structure on the substrate, the optical structure including an optical coating (e.g., optical coating 130) with an outer surface (e.g., outer surface 120a) that opposes the primary surface of the substrate in which the optical structure is disposed thereon. In a preferred aspect of the method 400, step 430 is conducted with a reactive sputter process and the optical structure formed by step 430 comprises a plurality of continuous layers.

Referring again to the method 400 of making a cover article 100 depicted in FIG. 4, the method further includes a step 440 of modifying the outer surface of the optical coating (e.g., outer surface 120a of the optical coating 130), wherein the outer surface of the optical coating has a surface roughness (Ra) less than 1.5 nm after the step of modifying the outer surface has been completed. In some aspects, the step 440 of modifying the outer surface of the optical coating can be conducted with one or more of an inductive coupled plasma (ICP) process, an ion beam (IB) process, a chemical etching process (e.g., with a plasma treatment in a CF₄ atmosphere), and a mechanical polishing process (e.g., with CeO₂ polishing media). In preferred embodiments, the step 440 of modifying the outer surface of the optical coating can be conducted with a plasma treatment process and/or a mechanical polishing process. In embodiments, as depicted in FIG. 4A, the step 440 of modifying the outer surface of the optical coating can be conducted in two steps 440a and 440b to remove a few nm of thickness of the optical coating (step 440a) and to reduce the roughness of the outer surface of the optical coating and further reduce its thickness (step 440b).

Still referring to the method 400 of making a cover article 100 depicted in FIG. 4, the method also includes a step 450 of depositing a functional coating (e.g., a functional coating 140, such as an easy-to-clean (ETC) coating) on the outer surface of the optical coating after the step 440 of modifying the outer surface. Further, the ETC coating formed in step 450 comprises a fluorine-containing material. In addition, the method 400 includes a step 460 of curing the ETC coating. Those skilled in the field of the disclosure can set the time and temperature for step 460 in view of the composition of the functional coating cured according to this step. Further, after step 460 of the method 400 has been completed, the resulting cover article (e.g., cover article 100 depicted in FIGS. 1A and 1B) comprises an optical structure with a physical thickness of greater than or equal to 500 nm and a maximum hardness of 10 GPa or greater, as measured on the outer surface of the optical coating by a Berkovich Indenter Test along an indentation depth of 50 nm or greater. Further, the scratch resistant layer of the optical structure has a physical thickness from 200 nm to 5000 nm. In addition, the functional coating (e.g., an ETC coating) exhibits a water contact angle of greater than 95° after 1000 cycles in a Steel Wool Abrasion Test after the step 460 of curing the ETC coating.

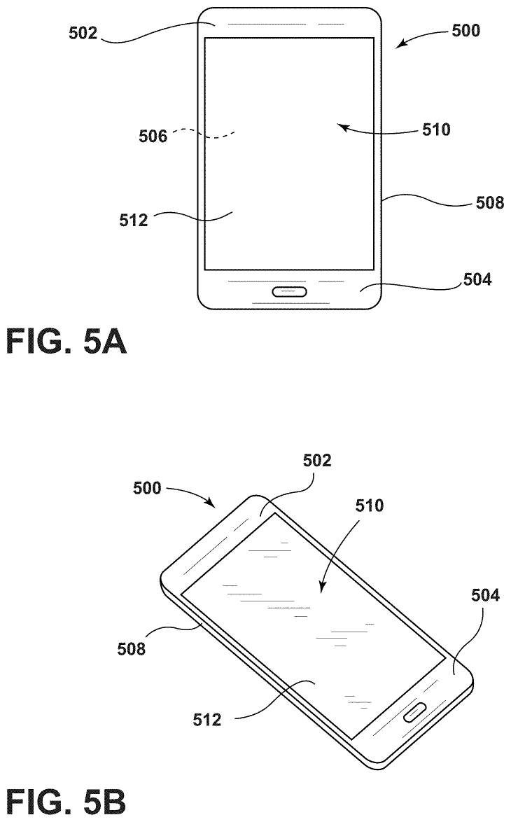

The cover articles 100 disclosed herein (e.g., as shown in FIGS. 1A and 1B) may be incorporated into a device article, for example, a device article with a display (or display device articles) (e.g., consumer electronics, including mobile phones, tablets, computers, navigation systems, wearable devices (e.g., watches) and the like), augmented-reality displays, heads-up displays, glasses-based displays, architectural device articles, transportation device articles (e.g., automotive, trains, aircraft, sea craft, etc.), appliance device articles, or any device that benefits from low reflectance, scratch resistance, abrasion resistance, damage resistance, or a combination thereof. An exemplary device article incorporating any of the articles disclosed herein (e.g., as consistent with the cover articles 100 depicted in FIGS. 1A and 1B) is shown in FIGS. 5A and 5B. Specifically, FIGS. 5A and 5B show a consumer electronic device 500 including a housing 502 having a front surface 504, a back surface 506, and side surfaces 508; electrical components (not shown) that are at least partially inside or entirely within the housing and including at least a controller, a memory, and a display 510 at or adjacent to the front surface of the housing; and cover substrate 512 at or over the front surface of the housing such that it is over the display. In some embodiments, the cover substrate 512 may include any of the cover articles 100 disclosed herein.

### EXAMPLES

The following examples describe various features and advantages provided by the disclosure, and are in no way intended to limit the invention and appended claims.

In these examples (Exs. 1A-1C; and Exs. 2A-2E) and comparative examples (i.e., Comp. Exs. 1A-1D; and Comp. Ex. 2), cover articles were formed according to the methods of the disclosure and as delineated below in Tables 2 and 3. More specifically, the optical structures of these examples, unless otherwise noted, were formed using a metal-mode, reactive sputtering process in a rotary drum coater, with independent control of sputtering power in the metal deposition and the inductively coupled plasma (ICP) (gas reaction) zones. Reactive gases (e.g., N₂ gas and O₂ gas) are isolated from the metal target in the ICP (gas reaction) zone. Further, the metal sputtering zone employs only inert gas flow (i.e., Ar gas).

### Comparative Example 1

Comparative cover articles including a strengthened glass substrate were prepared for this example with the structure delineated in FIGS. 2A-2C, as also described earlier in the disclosure. The glass substrate is an ion-exchanged, aluminosilicate glass substrate having a thickness of 550 μm and a refractive index of 1.509. The substrate has the following composition: 61.81% SiO₂; 3.9% B₂O₃; 19.69% Al₂O₃; 12.91% Na₂O; 0.018% K₂O; 1.43% MgO; 0.019% Fe₂O₃; and 0.223% SnO₂ (wt. %, on an oxide basis). The substrate was strengthened using a molten salt bath to achieve a maximum compressive stress (CS) of 850 MPa with a depth-of-layer (DOL) of 40 m.

As also depicted in FIGS. 2A-2C, three sets of comparative cover articles were prepared according to this example. In particular, one group was prepared with an easy-to-clean (ETC) coating on a substrate (Comp. Ex. 1A) and two groups were prepared with an easy-to-clean coating on each of two antireflective films having different surface roughness levels over a substrate (Comp. Exs. 1B and 1C). For the Comp. Ex. 1A comparative cover article 200a, the primary surface of the substrate has a surface roughness (Ra) of about 0.2 to 0.5 nm. For the Comp. Ex. 1B comparative cover article 200b, the ETC coating is disposed directly on the outer surface of an antireflective (AR) film (thickness of ˜0.5 μm), which is disposed on a primary surface of a strengthened glass substrate having a surface roughness (Ra) of about 1.5 nm. For the Comp. Ex. 1C comparative cover article 200c, the ETC coating is disposed directly on the outer surface of an antireflective (AR) film (thickness of ˜2.0 μm), which is disposed on a primary surface of a strengthened glass substrate having a surface roughness (Ra) of about 2.5 nm.

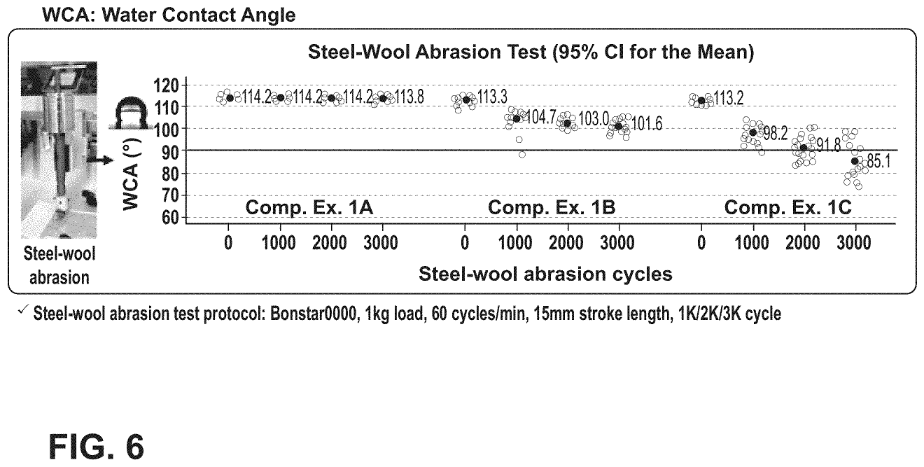

Referring to FIG. 6, a plot is provided of average water contact angle measurements on samples from the various comparative cover articles of this example, as subjected to a Steel Wool Abrasion Test for 0, 1000, 2000 and 3000 cycles (as employing a Bonstar #0000 abrader, 1 kg load, 60 cycles/min and a 15 mm stroke length). As shown in FIG. 6, the durability of the ETC coating of the comparative cover article Comp. Ex. 1A far exceeds that of the comparative cover articles Comp. Exs. 1B and 1C. That is, the ETC coating of Comp. Exs. 1B and 1C begins to show some degradation in contact angle at 2000 and 3000 cycles in the Steel Wool Abrasion Test. Further, as noted earlier, the surface roughness of the AR film on which the ETC coating has been deposited is significantly higher in Comp. Exs. 1B and 1C as compared to the control comparative article in which the ETC coating is deposited directly onto the glass substrate with a lower inherent surface roughness.

### Example 1

Cover articles including a strengthened glass substrate were prepared for this example with the structure delineated below in Table 2. The glass substrate is an ion-exchanged, aluminosilicate glass substrate having a thickness of 550 μm and a refractive index of 1.509. The substrate has the following composition: 61.81% SiO₂; 3.9% B₂O₃; 19.69% Al₂O₃; 12.91% Na₂O; 0.018% K₂O; 1.43% MgO; 0.019% Fe₂O₃; and 0.223% SnO₂ (wt. %, on an oxide basis). The substrate was strengthened using a molten salt bath to achieve a maximum compressive stress (CS) of 850 MPa with a depth-of-layer (DOL) of 40 m.

In this example, each of the samples listed in Table 2 below are cover articles with an antireflective optical structure having a thickness of about 0.5 μm disposed on a glass substrate. An ETC coating is disposed and cured upon the AR film structures in each of these examples according to the methods of the disclosure. More specifically, the comparative cover articles (Comp. Ex. 1D) are fabricated with no surface treatment to the outer surface of the AR film structure before application and curing of the ETC coating. In contrast, each of the inventive cover article examples (Exs. 1A-1C) were prepared in a manner similar to the comparative cover articles (Comp. Ex. 1D) except that the outer surface of the AR films of the inventive examples were subjected to an inductive coupled plasma (ICP) surface treatment step according to the methods of the disclosure according to the parameters listed below in Table 2.

TABLE 2
Exs. 1A-1C and Comp. Ex. 1D cover article processing conditions

| ICP Power | (no surface | 4 | | | 5 | | | | | | | 7 | | |
|---|---|---|---|---|---|---|---|---|---|---|---|---|---|---|
| (kW) | treatment) | | | | | | | | | | | | | |
| Duration | | 10 | 20 | 30 | 10 | | | 20 | 30 | | | 10 | 20 | 30 |
| (min) | | | | | | | | | | | | | | |
| Ar gas | | 80 | 80 | 80 | 80 | 40 | 80 | 80 | 80 | 40 | 160 | 80 | 80 | 80 |
| (sccm) | | | | | | | | | | | | | | |
| O2 gas | | — | — | — | — | 40 | 180 | — | — | — | — | — | — | — |
| (sccm) | | | | | | | | | | | | | | |

| Sample No. | Comp. Ex. 1D | | Ex. 1A | | | Ex. 1B | | |
|---|---|---|---|---|---|---|---|---|
| Avg. Ra (nm) | 1.81 | 1.88 | 1.61 | 1.40 | 1.28 | 1.60 | 1.70 | 1.83 |
| CA(°) SW 2K | 102.8 | 104.1 | 103.1 | 104.2 | 105.6 | 104.3 | 103.5 | 106.2 |
| CA(°) SW 3K | 101.9 | 101.8 | 102.5 | 105.3 | 104.7 | 103.9 | 102.5 | 102.0 |

| Sample No. | Ex. 1B | | | | Ex. 1C | | |
|---|---|---|---|---|---|---|---|
| Avg. Ra (nm) | 1.36 | 1.27 | 0.71 | 1.52 | 1.41 | 1.12 | 1.03 |
| CA(°) SW 2K | 106.5 | 105.9 | 109.2 | 103.7 | 105.5 | 106.8 | 107.4 |
| CA(°) SW 3K | 104.3 | 104.5 | 108.2 | 102.6 | 104.6 | 105.9 | 106.6 |

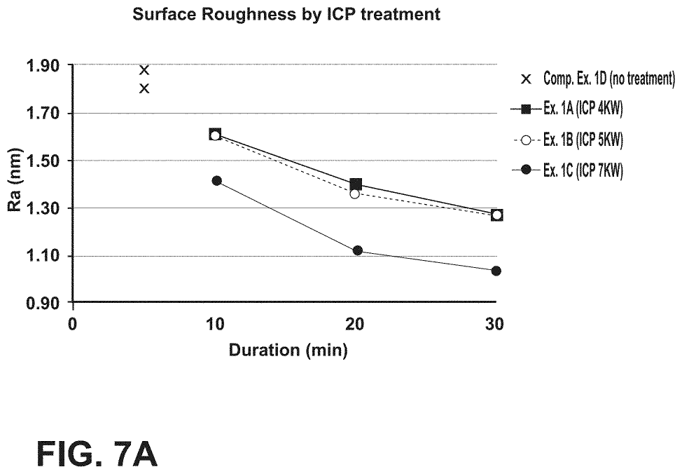

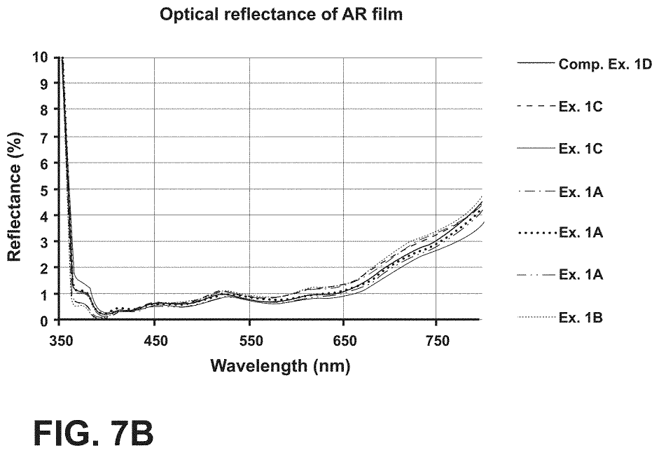

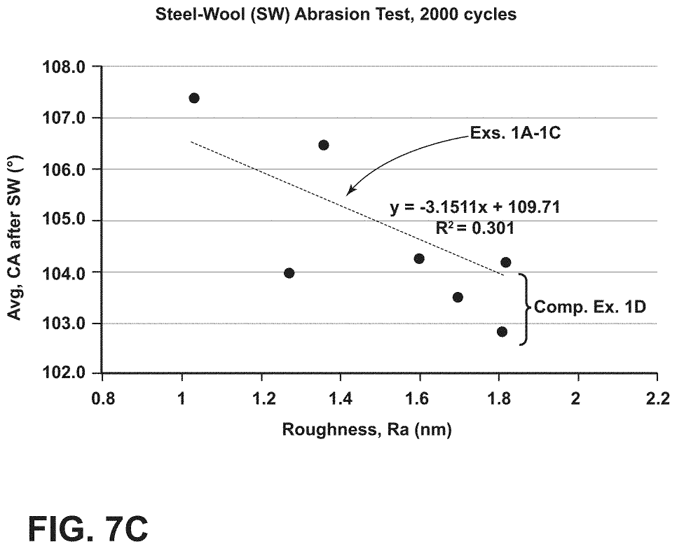

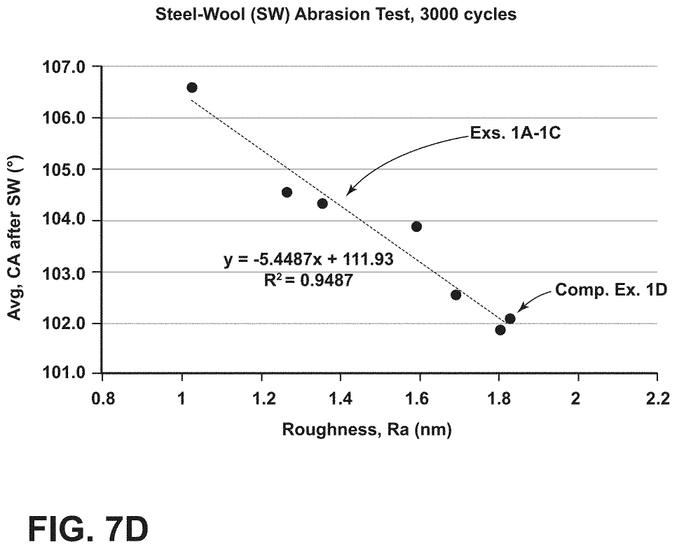

Referring now to FIG. 7A, a plot is provided of surface roughness vs. treatment time of the outer surface of the optical coating of the cover articles of this example, as subjected to plasma treatments at various power levels. As is evident in this figure, the surface roughness of the comparative examples (Comp. Ex. 1D) is the highest and the surface roughness of the inventive examples (Exs. 1A-1C) is substantially reduced as a function of surface treatment duration and ICP power levels.

Referring now to FIG. 7B, a plot is provided of first-surface reflectance vs. visible wavelengths for the cover articles of this example. As is evident from this figure, the reflectance levels of the comparative cover article and inventive cover articles of this example are substantially similar. Thus, the surface treatment approach employed in the inventive examples of this sample does not significantly degrade or otherwise influence reflectance in these examples.

Referring now to FIGS. 7C and 7D, plots are provided of average water contact angle measurements on the cover article samples of this example, as subjected to a Steel Wool Abrasion Test for 2000 and 3000 cycles (denoted in Table 2 above as “CA (°) SW 2K” and “CA (°) SW 3K”, respectively. As is evident from these figures, a clear correlation exists between surface roughness of the outer surface of the optical structure and the durability of the overlying ETC coating. That is, the comparative cover articles (Comp. Ex. 1D) have the highest levels of surface roughness of the surface (i.e., about 1.8 nm) on which the ETC is disposed and the lowest water contact angle after 2000 and 3000 cycles in the Steel Wool Abrasion Test. In contrast, the inventive cover articles (Exs. 1A-1C) with low levels of surface roughness (i.e., less than 1.5 nm) exhibit the highest water contact angles (≥104°) after 2000 and 3000 cycles in the Steel Wool Abrasion Test.

### Example 2

Cover articles including a strengthened glass substrate were prepared for this example with the structure delineated below in Table 3. The glass substrate is an ion-exchanged, aluminosilicate glass substrate having a thickness of 550 μm and a refractive index of 1.509. The substrate has the following composition: 61.810% SiO₂; 3.9% B₂O₃; 19.69% Al₂O₃; 12.91% Na₂O; 0.018% K₂O; 1.43% MgO; 0.019% Fe₂O₃; and 0.223% SnO₂ (wt. %, on an oxide basis). The substrate was strengthened using a molten salt bath to achieve a maximum compressive stress (CS) of 850 MPa with a depth-of-layer (DOL) of 40 m.

In this example, each of the samples listed in Table 3 below are cover articles with an antireflective optical structure having a thickness of about 2 μm disposed on a glass substrate. An ETC coating is disposed and cured upon the AR film structures in each of these examples according to the methods of the disclosure. More specifically, the comparative cover articles (Comp. Ex. 2) are fabricated with no surface treatment to the outer surface of the AR film structure before application and curing of the ETC coating. In contrast, each of the inventive cover article examples (Exs. 2A-2E) were prepared in a manner similar to the comparative cover articles (Comp. Ex. 2) except that the outer surface of the AR films of the inventive examples were subjected to a mechanical polishing surface treatment step according to the methods of the disclosure according to the parameters listed below in Table 3. In particular, CeO₂ polishing media was employed in the surface treatment step for the number of polishing cycles and polishing media concentration noted below in Table 3. As is evident in Table 3, surface roughness levels for the outer surface of the AR films of less than 1.8 nm can be achieved through mechanical polishing (Exs. 2A-2E) and surface roughness levels of less than 1.5 nm with 15 polishing cycles or more at a CeO₂ concentration of 10 wt. %.

TABLE 3
Exs. 2A-2E and Comp. Ex. 2 cover article processing conditions

| | | Comp. Ex. 2 | Ex. 2A | Ex. 2B | Ex. 2C | Ex. 2D | Ex. 2E |
|---|---|---|---|---|---|---|---|
| Test | CeO₂ | — | 10 wt. % | 10 wt. % | 10 wt. % | 10 wt. % | 10 wt. % |
| Condition | Concentration | | | | | | |
| | Polishing | — | 10 | 15 | 30 | 20 | 20 |
| | Cycles | | | | | | |
| Test | Surface | 2.75 | 1.79 | 1.42 | 0.93 | 0.76 | 0.31 |
| Results | Roughness | | | | | | |
| | (Ra, nm) | | | | | | |
| | Change in | — | (+0.83) | (+0.71) | −1.67 | −1.54 | −7.03 |
| | Capping Layer | | | | | | |
| | Thickness (nm) | | | | | | |
| | WaterCA(°) | 90 | 92 | 96 | 109 | 109 | 110 |
| | after SW 2K | | | | | | |
| | WaterCA(°) | 85 | 88 | 89 | 107 | 106 | 108 |
| | after SW 3K | | | | | | |

The various features described in the specification may be combined in any and all combinations, for example, as listed in the following embodiments.

Embodiment 1. A cover article is provided that includes: a substrate having a primary surface; an optical structure disposed on the primary surface, wherein the optical structure comprises an optical coating and a scratch resistant layer, and wherein the optical coating has an outer surface opposing the primary surface of the substrate; and an easy-to-clean (ETC) coating disposed on the outer surface of the optical coating, wherein the ETC coating comprises a fluorine-containing material. The outer surface of the optical coating has a surface roughness (Ra) less than 1.5 nm. The optical structure has a physical thickness of greater than or equal to 500 nm and a maximum hardness of 10 GPa or greater, as measured on the outer surface of the optical coating by a Berkovich Indenter Test along an indentation depth of 50 nm or greater. The scratch resistant layer has a physical thickness from 200 nm to 5000 nm.

Embodiment 2. The article according to Embodiment 1 is provided, wherein the outer surface of the optical coating has a surface roughness (Ra) less than 1.2 nm.

Embodiment 3. The article according to Embodiment 1 is provided, wherein the outer surface of the optical coating has a surface roughness (Ra) less than 1.0 nm.

Embodiment 4. The article according to any one of Embodiments 1-3 is provided, wherein the optical structure is derived from a plurality of continuous, sputtered layers.

Embodiment 5. The article according to any one of Embodiments 1-4 is provided, wherein the optical coating comprises a first low refractive index (RI) layer directly on and in contact with the primary surface of the substrate.

Embodiment 6. The article according to any one of Embodiments 1-5 is provided, wherein the optical coating is an antireflective (AR) coating, and further wherein the article exhibits a first-surface average photopic reflectance (% R) of less than 10% at any incident angle from about 5° to 20° from normal at wavelengths from 450 nm to 650 nm.

Embodiment 7. The article according to any one of Embodiments 1-5 is provided, wherein the optical coating is an antireflective (AR) coating, and further wherein the article exhibits a first-surface average photopic reflectance (% R) of less than 10% at any incident angle from about 5° to 20° from normal at wavelengths from 450 nm to 650 nm.

Embodiment 8. The article according to any one of Embodiments 1-5 is provided, wherein the optical coating is an antireflective (AR) coating, and further wherein the article exhibits a first-surface average photopic reflectance (% R) of less than 20% at any incident angle from about 5° to 20° from normal at wavelengths from 450 nm to 650 nm.

Embodiment 9. The article according to any one of Embodiments 1-8 is provided, wherein the ETC coating exhibits a water contact angle of greater than 95° after 1000 cycles in a Steel Wool Abrasion Test.

Embodiment 10. The article according to any one of Embodiments 1-8 is provided, wherein the ETC coating exhibits a water contact angle of greater than 105° after 3000 cycles in a Steel Wool Abrasion Test, and the physical thickness of the optical structure is about 1000 nm or greater.

Embodiment 11. The article according to any one of Embodiments 1-10 is provided, wherein the substrate is a strengthened-glass substrate or a glass-ceramic substrate.

Embodiment 12. A cover article is provided that includes: a substrate having a primary surface; an optical structure disposed on the primary surface, wherein the optical structure comprises an optical coating and a scratch resistant layer, and wherein the optical coating has an outer surface opposing the primary surface of the substrate; and an easy-to-clean (ETC) coating disposed on the outer surface of the optical coating, wherein the ETC coating comprises a fluorine-containing material. The outer surface of the optical coating has a surface roughness (Ra) less than 1.5 nm. The optical structure has a physical thickness of greater than or equal to 500 nm and a maximum hardness of 10 GPa or greater, as measured on the outer surface of the optical coating by a Berkovich Indenter Test along an indentation depth of 50 nm or greater. The scratch resistant layer has a physical thickness from 200 nm to 5000 nm. Further, the optical coating comprises a plurality of high refractive index (RI) layers and low RI layers, wherein each of the low RI layers comprises a refractive index of less than or equal to about 1.8, and each of the high RI layers comprises a refractive index of greater than 1.8. Each high RI layer comprises one of AlOₓN_{y}, Nb₂O, TiO₂, Si₃N₄, SiNₓ and SiOₓN_{y}, and each low RI layer comprises one of SiO₂, SiOₓ, and MgF₂. In addition, the scratch resistant layer comprises any one of AlOₓN_{y}, Si₃N₄, SiNₓ and SiOₓN_{y}.

Embodiment 13. The article according to Embodiment 12 is provided, wherein the outer surface of the optical coating has a surface roughness (Ra) less than 1.0 nm, wherein the ETC coating exhibits a water contact angle of greater than 105° after 3000 cycles in a Steel Wool Abrasion Test.

Embodiment 14. The article according to Embodiment 12 or Embodiment 13 is provided, wherein the optical structure is derived from a plurality of continuous, sputtered layers.

Embodiment 15. The article according to any one of Embodiments 12-14 is provided, wherein the optical coating comprises a first low refractive index (RI) layer directly on and in contact with the primary surface of the substrate.

Embodiment 16. The article according to any one of Embodiments 12-15 is provided, wherein the substrate is a strengthened-glass substrate or a glass-ceramic substrate.

Embodiment 17. A cover article is provided that includes: a substrate having a primary surface; an optical structure disposed on the primary surface, wherein the optical structure comprises an optical coating and a scratch resistant layer, and wherein the optical coating has an outer surface opposing the primary surface of the substrate; and an easy-to-clean (ETC) coating disposed on the outer surface of the optical coating, wherein the ETC coating comprises a fluorine-containing material. The outer surface of the optical coating has a surface roughness (Ra) less than 1.5 nm. The optical structure has a physical thickness of greater than or equal to 750 nm and a maximum hardness of 10 GPa or greater, as measured on the outer surface of the optical coating by a Berkovich Indenter Test along an indentation depth of 50 nm or greater. The scratch resistant layer has a physical thickness from 250 nm to 2500 nm. In addition, the scratch resistant layer is within the optical coating. Further, the optical coating comprises a plurality of high refractive index (RI) layers and low RI layers, wherein each of the low RI layers comprises a refractive index of less than or equal to about 1.8, and each of the high RI layers comprises a refractive index of greater than 1.8. Each high RI layer comprises one of Si₃N₄, SiNₓ and SiOₓN_{y}, and each low RI layer comprises one of SiO₂ and SiOₓ. In addition, the scratch resistant layer comprises any one of Si₃N₄, SiNₓ and SiOₓN_{y}.

Embodiment 18. The article according to Embodiment 17 is provided, wherein the outer surface of the optical coating has a surface roughness (Ra) less than 1.2 nm.

Embodiment 19. The article according to Embodiment 17 or Embodiment 18 is provided, wherein the optical structure is derived from a plurality of continuous, sputtered layers.

Embodiment 20. The article according to any one of Embodiments 17-19 is provided, wherein the optical coating comprises a first low refractive index (RI) layer directly on and in contact with the primary surface of the substrate.

Embodiment 21. The article according to any one of Embodiments 17-20 is provided, wherein the substrate is a strengthened-glass substrate or a glass-ceramic substrate.

Embodiment 22. A consumer electronic product is provided that includes: a housing comprising a front surface, a back surface and side surfaces; electronic components at least partially within the housing; and a cover disposed over at least one of the display and the sensor. The electronic components comprise at least one of a display and a sensor. The display is at or adjacent to the front surface of the housing and the sensor is at or adjacent to the front surface or the back surface of the housing. Further, at least one portion of the cover comprises the cover article of any one of Embodiments 1-11.

Embodiment 23. A consumer electronic product is provided that includes: a housing comprising a front surface, a back surface and side surfaces; electronic components at least partially within the housing; and a cover disposed over at least one of the display and the sensor. The electronic components comprise at least one of a display and a sensor. The display is at or adjacent to the front surface of the housing and the sensor is at or adjacent to the front surface or the back surface of the housing. Further, at least one portion of the cover comprises the cover article of any one of Embodiments 12-16.

Embodiment 24. A consumer electronic product is provided that includes: a housing comprising a front surface, a back surface and side surfaces; electronic components at least partially within the housing; and a cover disposed over at least one of the display and the sensor. The electronic components comprises at least one of a display and a sensor. The display is at or adjacent to the front surface of the housing and the sensor is at or adjacent to the front surface or the back surface of the housing. At least one portion of the cover comprises the cover article of any one of Embodiments 17-21.

Embodiment 25. A method of making a cover article is provided that includes: providing a substrate having a primary surface; depositing an optical structure on the primary surface, wherein the optical structure comprises an optical coating and a scratch resistant layer, and wherein the optical coating has an outer surface opposing the primary surface of the substrate; modifying the outer surface of the optical coating, wherein the outer surface of the optical coating has a surface roughness (Ra) less than 1.5 nm after the step of modifying the outer surface; depositing an easy-to-clean (ETC) coating on the outer surface of the optical coating after the step of modifying the outer surface, wherein the ETC coating comprises a fluorine-containing material; and curing the ETC coating. The optical structure has a physical thickness of greater than or equal to 500 nm and a maximum hardness of 10 GPa or greater, as measured on the outer surface of the optical coating by a Berkovich Indenter Test along an indentation depth of 50 nm or greater. Further, the scratch resistant layer has a physical thickness from 200 nm to 5000 nm. In addition, the ETC coating exhibits a water contact angle of greater than 95° after 1000 cycles in a Steel Wool Abrasion Test after the step of curing the ETC coating.

Embodiment 26. The method according to Embodiment 25, wherein the step of depositing an optical structure is conducted with a reactive sputter process, and further wherein the optical structure comprises a plurality of continuous layers.

Embodiment 27. The method according to Embodiment 25 or Embodiment 26, wherein the step of modifying the outer surface of the optical coating is conducted with a plasma treatment process.

Embodiment 28. The method according to Embodiment 25 or Embodiment 26, wherein the step of modifying the outer surface of the optical coating is conducted with a mechanical polishing process.

Many variations and modifications may be made to the above-described embodiments of the disclosure without departing substantially from the spirit and various principles of the disclosure. All such modifications and variations are intended to be included herein within the scope of this disclosure and protected by the following claims.

What is claimed is:

1. A cover article, comprising:
a substrate having a primary surface;
an optical structure disposed on the primary surface, wherein the optical structure comprises an optical coating and a scratch resistant layer, and wherein the optical coating has an outer surface opposing the primary surface of the substrate; and
an easy-to-clean (ETC) coating disposed on the outer surface of the optical coating, wherein the ETC coating comprises a fluorine-containing material,
wherein the outer surface of the optical coating has a surface roughness (Ra) less than 1.5 nm,
wherein the optical structure has a physical thickness of greater than or equal to 500 nm and a maximum hardness of 10 GPa or greater, as measured on the outer surface of the optical coating by a Berkovich Indenter Test along an indentation depth of 50 nm or greater, and
further wherein the scratch resistant layer has a physical thickness from 200 nm to 5000 nm.

2. The cover article according to claim 1, wherein the outer surface of the optical coating has a surface roughness (Ra) less than 1.2 nm.

3. The cover article according to claim 1, wherein the outer surface of the optical coating has a surface roughness (Ra) less than 1.0 nm.

4. The cover article according to claim 1, wherein the optical structure is derived from a plurality of continuous, sputtered layers.

5. The cover article according to claim 1, wherein the optical coating comprises a first low refractive index (RI) layer directly on and in contact with the primary surface of the substrate.

6. The cover article according to claim 1, wherein the optical coating is an antireflective (AR) coating, and further wherein the article exhibits a first-surface average photopic reflectance (% R) of less than 1% at any incident angle from about 5° to 20° from normal at wavelengths from 450 nm to 650 nm.

7. The cover article according to claim 1, wherein the optical coating is an antireflective (AR) coating, and further wherein the article exhibits a first-surface average photopic reflectance (% R) of less than 10% at any incident angle from about 5° to 20° from normal at wavelengths from 450 nm to 650 nm.

8. The cover article according to claim 1, wherein the optical coating is an antireflective (AR) coating, and further wherein the article exhibits a first-surface average photopic reflectance (% R) of less than 20% at any incident angle from about 5° to 20° from normal at wavelengths from 450 nm to 650 nm.

9. The cover article according to claim 1, wherein the ETC coating exhibits a water contact angle of greater than 95° after 1000 cycles in a Steel Wool Abrasion Test.

10. The cover article according to claim 1, wherein the ETC coating exhibits a water contact angle of greater than 105° after 3000 cycles in a Steel Wool Abrasion Test, and the physical thickness of the optical structure is about 1000 nm or greater.

11. The cover article according to claim 1, wherein the substrate is a strengthened-glass substrate or a glass-ceramic substrate.

12. A cover article, comprising:
a substrate having a primary surface;
an optical structure disposed on the primary surface, wherein the optical structure comprises an optical coating and a scratch resistant layer, and wherein the optical coating has an outer surface opposing the primary surface of the substrate; and
an easy-to-clean (ETC) coating disposed on the outer surface of the optical coating, wherein the ETC coating comprises a fluorine-containing material,
wherein the outer surface of the optical coating has a surface roughness (Ra) less than 1.5 nm,
wherein the optical structure has a physical thickness of greater than or equal to 500 nm and a maximum hardness of 10 GPa or greater, as measured on the outer surface of the optical coating by a Berkovich Indenter Test along an indentation depth of 50 nm or greater,
wherein the scratch resistant layer has a physical thickness from 200 nm to 5000 nm,
wherein the optical coating comprises a plurality of high refractive index (RI) layers and low RI layers, wherein each of the low RI layers comprises a refractive index of less than or equal to about 1.8, and each of the high RI layers comprises a refractive index of greater than 1.8,
wherein each high RI layer comprises one of AlOₓN_{y}, Nb₂O, TiO₂, Si₃N₄, SiNₓ and SiOₓN_{y}, and wherein each low RI layer comprises one of SiO₂, SiOₓ, and MgF₂, and
further wherein the scratch resistant layer comprises any one of AlOₓN_{y}, Si₃N₄, SiNₓ and SiOₓN_{y}.

13. The cover article according to claim 12, wherein the outer surface of the optical coating has a surface roughness (Ra) less than 1.0 nm, wherein the ETC coating exhibits a water contact angle of greater than 105° after 3000 cycles in a Steel Wool Abrasion Test.

14. The cover article according to claim 12, wherein the optical structure is derived from a plurality of continuous, sputtered layers.

15. The cover article according to claim 12, wherein the optical coating comprises a first low refractive index (RI) layer directly on and in contact with the primary surface of the substrate.

16. The cover article according to claim 12, wherein the substrate is a strengthened-glass substrate or a glass-ceramic substrate.

17. A cover article, comprising:
a substrate having a primary surface;
an optical structure disposed on the primary surface, wherein the optical structure comprises an optical coating and a scratch resistant layer, and wherein the optical coating has an outer surface opposing the primary surface of the substrate; and
an easy-to-clean (ETC) coating disposed on the outer surface of the optical coating, wherein the ETC coating comprises a fluorine-containing material,
wherein the outer surface of the optical coating has a surface roughness (Ra) less than 1.5 nm,
wherein the optical structure has a physical thickness of greater than or equal to 750 nm and a maximum hardness of 10 GPa or greater, as measured on the outer surface of the optical coating by a Berkovich Indenter Test along an indentation depth of 50 nm or greater,
wherein the scratch resistant layer has a physical thickness from 250 nm to 2500 nm,
wherein the scratch resistant layer is within the optical coating,
wherein the optical coating comprises a plurality of high refractive index (RI) layers and low RI layers, wherein each of the low RI layers comprises a refractive index of less than or equal to about 1.8, and each of the high RI layers comprises a refractive index of greater than 1.8,
wherein each high RI layer comprises one of Si₃N₄, SiNₓ and SiOₓN_{y}, and wherein each low RI layer comprises one of SiO₂ and SiOₓ, and
further wherein the scratch resistant layer comprises any one of Si₃N₄, SiNₓ and SiOₓN_{y}.

18. The cover article according to claim 17, wherein the outer surface of the optical coating has a surface roughness (Ra) less than 1.2 nm.

19. The cover article according to claim 17, wherein the optical structure is derived from a plurality of continuous, sputtered layers.

20. The cover article according to claim 17, wherein the optical coating comprises a first low refractive index (RI) layer directly on and in contact with the primary surface of the substrate.

21. The cover article according to claim 17, wherein the substrate is a strengthened-glass substrate or a glass-ceramic substrate.

22. A consumer electronic product, comprising:
a housing comprising a front surface, a back surface and side surfaces;
electronic components at least partially within the housing, the electronic components comprising at least one of a display and a sensor, the display at or adjacent to the front surface of the housing and the sensor at or adjacent to the front surface or the back surface of the housing; and
a cover disposed over at least one of the display and the sensor,
wherein at least one portion of the cover comprises the cover article of claim 1.

23. A consumer electronic product, comprising:
a housing comprising a front surface, a back surface and side surfaces;
electronic components at least partially within the housing, the electronic components comprising at least one of a display and a sensor, the display at or adjacent to the front surface of the housing and the sensor at or adjacent to the front surface or the back surface of the housing; and
a cover disposed over at least one of the display and the sensor,
wherein at least one portion of the cover comprises the cover article of claim 12.

24. A consumer electronic product, comprising:
a housing comprising a front surface, a back surface and side surfaces;
electronic components at least partially within the housing, the electronic components comprising at least one of a display and a sensor, the display at or adjacent to the front surface of the housing and the sensor at or adjacent to the front surface or the back surface of the housing; and
a cover disposed over at least one of the display and the sensor,
wherein at least one portion of the cover comprises the cover article of claim 17.

25. A method of making a cover article, comprising:
providing a substrate having a primary surface;
depositing an optical structure on the primary surface, wherein the optical structure comprises an optical coating and a scratch resistant layer, and wherein the optical coating has an outer surface opposing the primary surface of the substrate;
modifying the outer surface of the optical coating, wherein the outer surface of the optical coating has a surface roughness (Ra) less than 1.5 nm after the step of modifying the outer surface;
depositing an easy-to-clean (ETC) coating on the outer surface of the optical coating after the step of modifying the outer surface, wherein the ETC coating comprises a fluorine-containing material; and
curing the ETC coating,
wherein the optical structure has a physical thickness of greater than or equal to 500 nm and a maximum hardness of 10 GPa or greater, as measured on the outer surface of the optical coating by a Berkovich Indenter Test along an indentation depth of 50 nm or greater,
wherein the scratch resistant layer has a physical thickness from 200 nm to 5000 nm, and
further wherein the ETC coating exhibits a water contact angle of greater than 95° after 1000 cycles in a Steel Wool Abrasion Test after the step of curing the ETC coating.

26. The method according to claim 25, wherein the step of depositing an optical structure is conducted with a reactive sputter process, and further wherein the optical structure comprises a plurality of continuous layers.

27. The method according to claim 25, wherein the step of modifying the outer surface of the optical coating is conducted with a plasma treatment process.

28. The method according to claim 25, wherein the step of modifying the outer surface of the optical coating is conducted with a mechanical polishing process.
